(19) United States
(12) Patent Application Publication
(10) Pub. No.: US 2026/0032913 A1
(43) Pub. Date: Jan. 29, 2026

(54) MEMORY DEVICE INCLUDING CONTROL GATES HAVING PARTIAL DIELECTRIC LINERS

(71) Applicant: Micron Technology, Inc., Boise, ID (US)

(72) Inventors: Giovanni Mazzone, Villasanta, MI (US); Emilio Camerlenghi, Bergamo (IT); Sidhartha Gupta, Boise, ID (US); Paolo Tessariol, Arcore (IT); Davide Resnati, Milano, MI (US); Chet E. Carter, Boise, ID (US); Tyler List, Boise, ID (US); Giovanni Maria Paolucci, Milano (IT)

(21) Appl. No.: 19/283,806

(22) Filed: Jul. 29, 2025

Related U.S. Application Data
(60) Provisional application No. 63/676,755, filed on Jul. 29, 2024.

(51) Int. Cl. H10B 43/35; H10B 41/10; H10B 41/27; H10B 41/35; H10B 43/10; H10B 43/27

(52) U.S. Cl. CPC H10B 43/35; H10B 41/10; H10B 41/27; H10B 41/35; H10B 43/10; H10B 43/27

(57) ABSTRACT

Some embodiments include apparatuses and methods of forming the apparatuses. One of the apparatuses includes: first memory cells and an associated first control gate located on a first level of the apparatus; second memory cells and an associated second control gate located on a second level of the apparatus; a level of dielectric material between the first and second control gates; the second control gate including a conductive material, and a first dielectric liner and a second dielectric liner adjacent respective sides of the conductive material; the second dielectric liner including an opening adjacent a portion of the conductive material; the first dielectric liner extending continuously at the portion of the conductive material; and a conductive contact extending through the first control gate, the level of dielectric material, and the opening of the second dielectric liner and contacting the conductive material of the second control gate.

### PRIORITY APPLICATION

This application claims the benefit of priority to U.S. Provisional Application Ser. No. 63/676,755, filed Jul. 29, 2024, which is incorporated herein by reference in its entirety.

### BACKGROUND

A memory device (e.g., a flash memory device) has memory cells for storing information, and associated control gates to control access to the memory cells. The dimensions of some components of a memory device can be relatively small (e.g., in nanometer size). At a certain small dimension of some memory devices, it can be a challenge to maintain proper electrical isolation between control gates in such memory devices. Improper electrical isolation can impact performance and reliability of such memory devices.

### BRIEF DESCRIPTION OF THE DRAWINGS

FIG. 1 shows a block diagram of an apparatus in the form of a memory device, according to some embodiments described herein.

FIG. 2 shows a general schematic diagram of a portion of a memory device including a memory array having blocks (blocks of memory cells) and sub-blocks in each of the blocks, according to some embodiments described herein.

FIG. 3A shows a detailed schematic diagram of two blocks of the memory device of FIG. 2, according to some embodiments described herein.

FIG. 3B shows an example of the memory device of FIG. 3A including multiple drain select gates, according to some embodiments described herein.

FIG. 4 shows a top view of a structure of a portion of the memory device of FIG. 3A including a region of memory array including blocks, dielectric structures between the blocks, data lines extending over the blocks, and a conductive contact region, according to some embodiments described herein.

FIG. 5A shows a side view (e.g., cross-section) of a structure of a portion of the memory device of FIG. 4, including tiers of materials that include respective memory cells and control gates associated with the memory cells, according to some embodiments described herein.

FIG. 5B shows a variation of the memory device of FIG. 5A, including a memory cell pillar associated with multiple drain select gates, according to some embodiments described herein.

FIG. 6A shows a top view of the structure of the memory device of FIG. 4 and FIG. 5A, including conductive contacts and memory cell pillars, according to some embodiments described herein.

FIG. 6B shows a top view of the structure of the memory device of FIG. 6A, including conductive lines coupled to the conductive contacts, according to some embodiments described herein.

FIG. 7A, FIG. 7B, FIG. 7C, FIG. 7D, and FIG. 7E show different views of the memory device, according to some embodiments described herein.

FIG. 7F, FIG. 7G, FIG. 7H, FIG. 7I, FIG. 7J, and FIG. 7K show different views of a memory device that can be a variation of the memory device of FIG. 7A.

FIG. 8A, FIG. 8B, FIG. 8C, and FIG. 8D different memory devices that can be different variations of the memory device of FIG. 7A, according to some embodiments described herein.

FIG. 9 shows a memory device that can be a variation of the memory device shown in FIG. 6A, according to some embodiments described herein.

FIG. 10 through FIG. 26B show different views of elements during processes of forming a memory device including forming conductive contacts of the memory device, according to some embodiments described herein.

### DETAILED DESCRIPTION

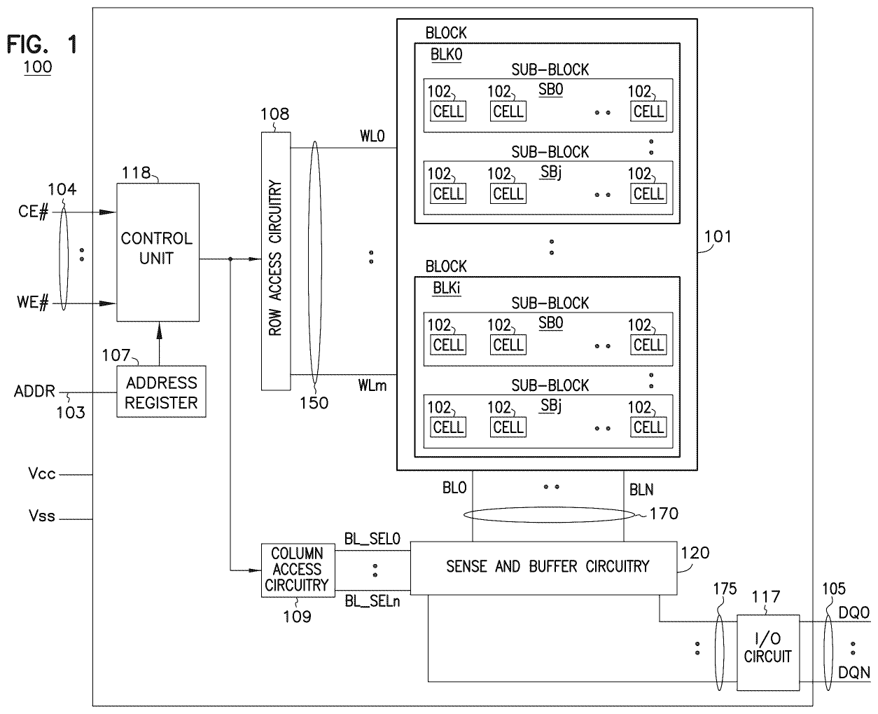

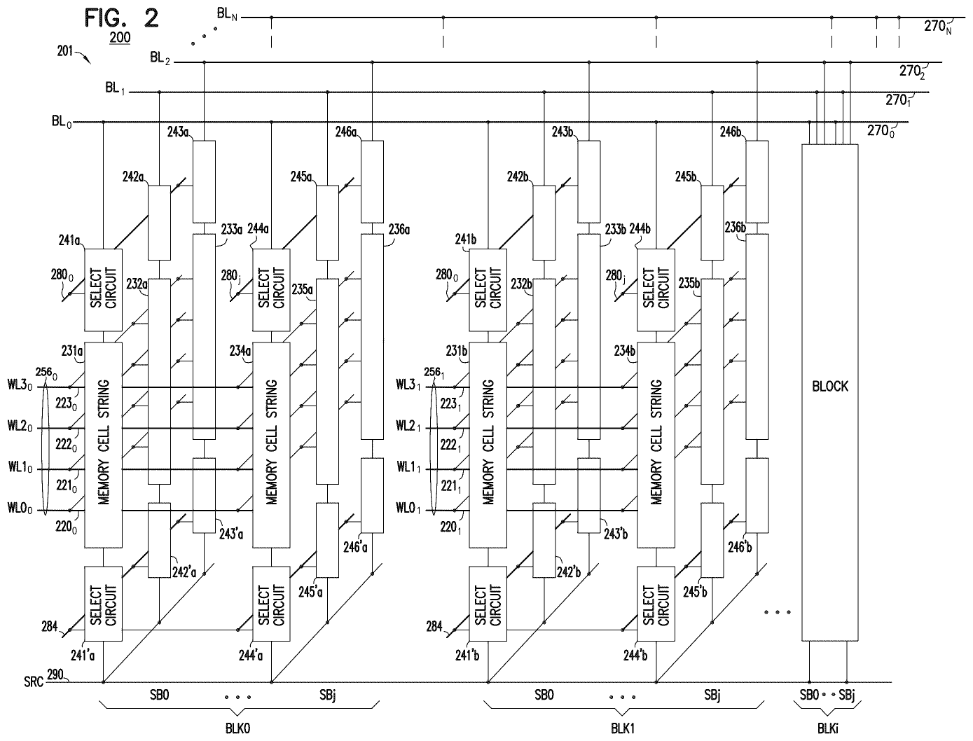

The techniques described herein involve a memory device including levels of memory cells (tiers of memory cells) and associated control gates. Each control gate can include respective dielectric liners and a conductive material between the dielectric liners. The dielectric liners can be part of electrical isolation between adjacent control gates. The memory device also includes conductive contacts associated with the control gates. Each control gate can be coupled to a respective control gate. A conductive contact can extend through an opening in one of the dielectric liners (e.g., the top dielectric liner) of a respective control gate to couple to (contact) the conductive material of the respective control gate. The conductive contact can extend at least partially into the conductive material of the respective control gate. The conductive contact may not extend through the other dielectric liner (e.g., the bottom dielectric liner) of the respective control gate. Thus, one of the dielectric liners (e.g., the bottom dielectric liner) of the respective control gate can extend continuously at a contact region where the conductive contact contacts the conductive material of the respective control gate. The structure of the described conductive contacts and control gates can improve electrical isolation between adjacent control gates. This, in turn, can improve operations, performance, and reliability of the memory device. Other structures and improvements and benefits of the memory devices are further discussed below with reference to FIG. 1 through FIG. 26B.

FIG. 1 shows a block diagram of an apparatus in the form of a memory device 100, according to some embodiments described herein. Memory device 100 can include a memory array (or multiple memory arrays) 101 containing memory cells 102 arranged in blocks (blocks of memory cells), such as blocks BLK0 through BLKi. Each of blocks BLK0 through BLKi can include its own sub-blocks, such as sub-blocks SB0 through SBj. A sub-block is a portion of a block. In the physical structure of memory device 100, memory cells 102 can be arranged vertically (e.g., stacked one over another) over a substrate (e.g., a semiconductor substrate) of memory device 100.

As shown in FIG. 1, memory device 100 can include access lines (which can include word lines) 150 and data lines (which can include bit lines) 170. Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks BLK0 through BLKi and data lines 170 to selectively exchange information (e.g., data) with memory cells 102 of blocks BLK0 through BLKi. Data lines 170 can be shared among blocks BLK0 through BLKi.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which sub-blocks of blocks BLK0 through BLKi are to be accessed during a memory operation. Memory device 100 can perform a read operation to read (e.g., sense) information (e.g., previously stored information) from memory cells 102 of blocks BLK0 through BLKi, or a write (e.g., programming) operation to store (e.g., program) information in memory cells 102 of blocks BLK0 through BLKi. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks BLK0 through BLKi.

Memory device 100 can include a control unit 118 that can be configured to control memory operations of memory device 100 based on control signals on lines 104. Examples of the control signals on lines 104 include one or more clock signals and other signals (e.g., a chip enable signal CE #, a write enable signal WE #) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that causes memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks BLK0 through BLKi and provide the value of the information to lines (e.g., global data lines) 175. Sense and buffer circuitry 120 can also be configured to use signals on lines 175 to determine the value of information to be stored (e.g., programmed) in memory cells 102 of blocks BLK0 through BLKi (e.g., during a write operation) based on the values (e.g., voltage values) of signals on lines 175 (e.g., during a write operation).

Memory device 100 can include input/output (I/O) circuitry 117 to exchange information between memory cells 102 of blocks BLK0 through BLKi and lines (e.g., I/O lines) 105. Signals DQ0 through DQN on lines 105 can represent information read from or stored in memory cells 102 of blocks BLK0 through BLKi. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits (e.g., more than three bits in each memory cell). A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3D NAND) or a NOR flash memory device, or another kind of memory device, such as a variable resistance memory device (e.g., a phase change memory device or a resistive Random Access Memory (RAM) device).

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 26BB.

FIG. 2 shows a general schematic diagram of a portion of a memory device 200 including a memory array 201 having blocks (blocks of memory cells) BLK0 through BLKi and sub-blocks SB0 through SBj in each of the blocks, according to some embodiments described herein. Memory device 200 can correspond to memory device 100 of FIG. 1. For example, memory array 201 can form part of memory array 101 of FIG. 1.

As shown in FIG. 2, each sub-block (e.g., SB0 or SBj) has its own memory cell strings that can be associated with (e.g., coupled to) respective select circuits. The sub-blocks of the blocks (e.g., blocks BLK0 through BLKi) of memory device 200 can have the same number of memory cell strings and associated select circuits. For example, sub-block SB0 of block BLK0 has memory cell strings 231a, 232a, and 233a and associated select circuits (e.g., drain select circuits) 241a, 242a, and 243a, respectively, and select circuits (e.g., source select circuits) 241′a, 242′a, and 243′a, respectively. In another example, sub-block SBj of block BLK0 has memory cell strings 234a, 235a, and 236a and associated select circuits (e.g., drain select circuits) 244a, 245a, and 246a, respectively, and select circuits (e.g., source select circuits) 244′a, 245′a, and 246′a, respectively.

Similarly, sub-block SB0 of block BLK1 has memory cell strings 231b, 232b, and 233b, and associated select circuits (e.g., drain select circuits) 241b, 242b, and 243b, respectively, and select circuits (e.g., source select circuits) 241′b, 242′b, and 243′b, respectively. Sub-block SBj of block BLK1 has memory cell strings 234b, 235b, and 236b, and associated select circuits (e.g., drain select circuits) 244b, 245b, and 246b, respectively, and select circuits (e.g., source select circuits) 244′b, 245′b, and 246′b, respectively.

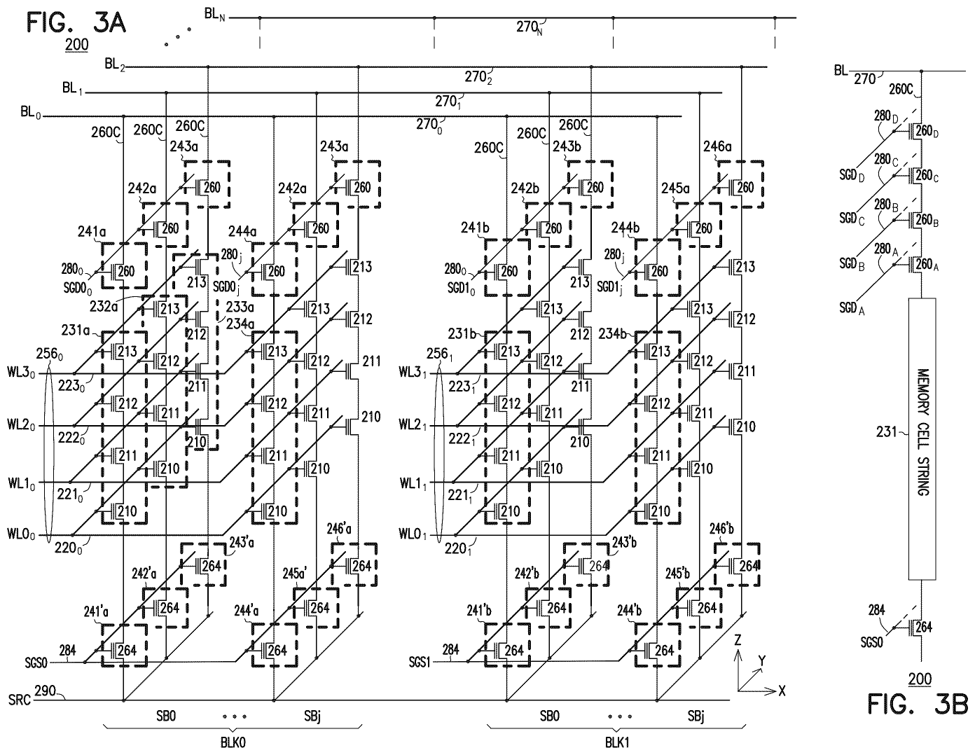

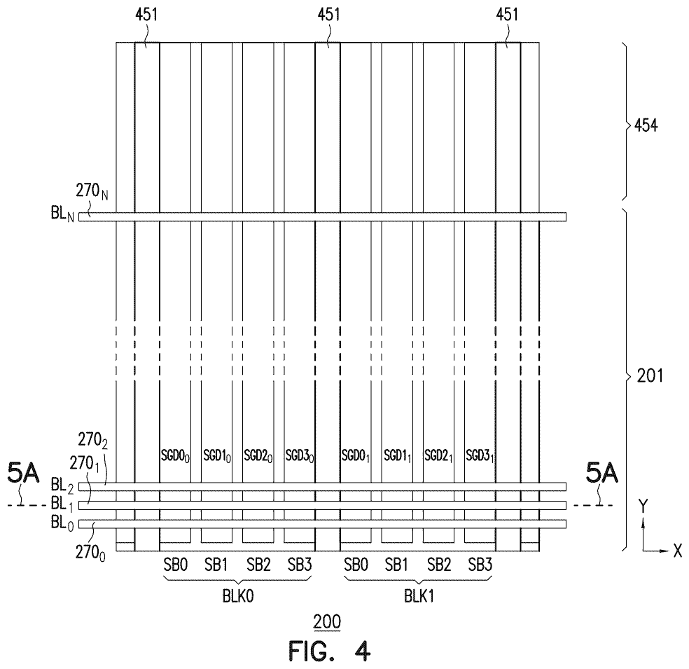

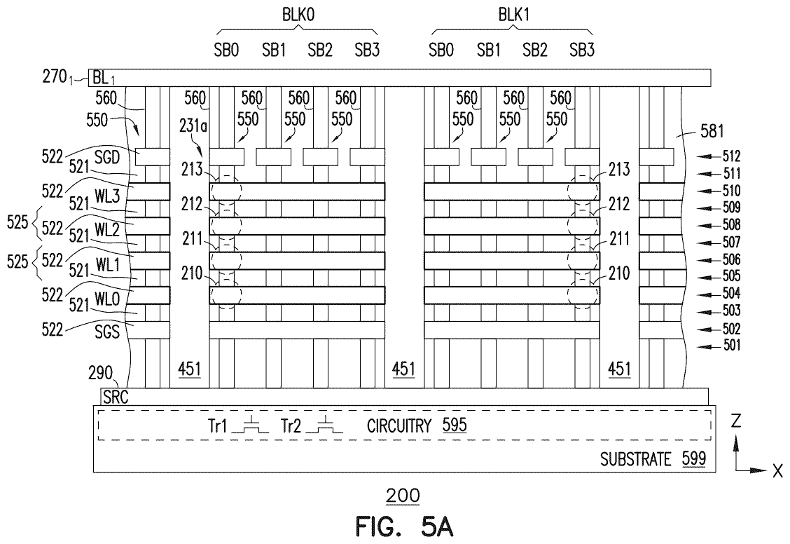

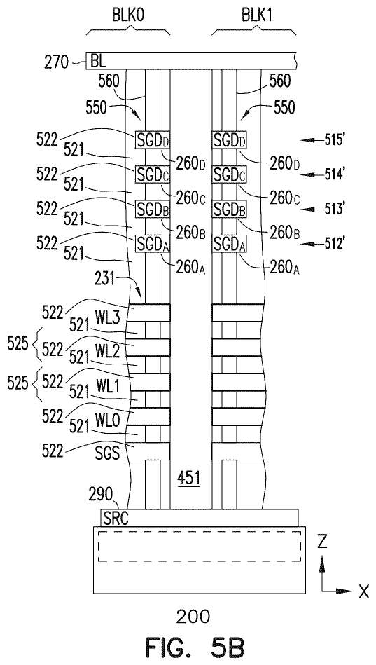

FIG. 2 shows an example of three memory cell strings and their associated circuits in a sub-block (e.g., in sub-block SB0). The number of memory cell strings and their associated select circuits in each sub-block of blocks BLK0 through BLKi can vary. Each of the memory cell strings of memory device 200 can include series-connected memory cells (shown in detail in FIG. 3A and FIG. 4) and a pillar (e.g., pillar 550 in FIG. 5A) where the series-connected memory cells can be located (e.g., vertically located) along a respective portion of the pillar.

As shown in FIG. 2, memory device 200 can include data lines 270₀ through 270_{N} that carry signals BL₀ through BL_{N}, respectively. Each of data lines 270₀ through 270_{N} can be structured as a conductive line that can include conductive materials (e.g., conductively doped polycrystalline silicon (doped polysilicon), metals, or other conductive materials).

Blocks BLK0 through BLKi can share data lines 270₀ through 270_{N} to carry information (in the form of signals) read from or to be stored in memory cells of selected memory cells (e.g., selected memory cells in block BLK0 or BLK1) of memory device 200. Memory cell strings of different subblocks from the same block (and from different blocks) can share the same data line. For example, memory cell strings 231a, 234a (of block BLK0), 231b and 234b (of block BLK1) can share data line 270₀. Memory cell strings 232a, 235a (of block BLK0), 232b and 235b (of block BLK1) can share data line 2701. Memory cell strings 233a, 236a (of block BLK0), 233b and 236b (of block BLK1) can share data line 270₂.

Memory device 200 can include a source (e.g., a source line, a source plate, or a source region) 290 that can carry a signal (e.g., a source line signal) SRC. Source 290 can be structured as a conductive line or a conductive plate (e.g., conductive region) of memory device 200. Source 290 can be a common source (e.g., common source plate or common source region) of blocks BLK0 through BLKi. Alternatively, each of blocks BLK0 through BLKi can have its own source similar to source 290. Source 290 can be coupled to a ground connection of memory device 200.

Each of the blocks BLK0 through BLKi can have its own group of control gates for controlling access to memory cells of the memory cell strings of the sub-block of a respective block. As shown in FIG. 2, memory device 200 can include control gates (e.g., word lines) 220₀, 221₀, 222₀, and 223₀ in block BLK0 that can be part of conductive paths (e.g., access lines) 256₀ of memory device 200. Memory device 200 can include control gates (e.g., word lines) 220₁, 221₁, 222₁, and 223₁ in block BLK1 that can be part of other conductive paths (e.g., access lines) 256₁ of memory device 200. Conductive paths 256₀ and 256₁ can correspond to part of access lines 150 of memory device 100 of FIG. 1.

As shown in FIG. 2, control gates 220₀, 221₀, 222₀, and 223₀ can be electrically separated from each other. Control gates 220₁, 221₁, 222₁, and 223₁ can be electrically separated from each other. Control gates 220₀, 221₀, 222₀, and 223₀ can be electrically separated from control gates 220₁, 221₁, 222₁, and 223₁. Thus, blocks BLK0 through BLKi can be accessed separately (e.g., accessed one at a time).

FIG. 2 shows memory device 200 including four control gates in each of blocks BLK0 through BLKi as an example. The number of control gates of the blocks (e.g., blocks BLK0 through BLKi) of memory device 200 can be different from four. For example, each of blocks BLK0 through BLKi can include up to hundreds of control gates (or more than hundreds of control gates).

Each of control gates 220₀, 221₀, 222₀, and 223₀ can be part of a structure (e.g., a level) of a conductive material (e.g., a layer of conductive material) located in a level of memory device 200. Control gates 220₀, 221₀, 222₀, and 223₀ can carry corresponding signals (e.g., word line signals) WL0₀, WL1₀, WL2₀, and WL30. Memory device 200 can use signals WL0₀, WL1₀, WL2₀, and WL3₀ to selectively control access to memory cells of block BLK0 during an operation (e.g., read, write, or erase operation).

Each of control gates 220₁, 221₁, 222₁, and 223₁ can be part of a structure (e.g., a level) of a conductive material (e.g., a layer of conductive material) located in a level of memory device 200. Control gates 220₁, 221₁, 222₁, and 223₁ can carry corresponding signals (e.g., word line signals) WL0₁, WL1₁, WL2₁, and WL3₁. Memory device 200 can use signals WL0₁, WL1₁, WL2₁, and WL3₁ to selectively control access to memory cells of block BLK1 during an operation (e.g., read, write, or erase operation).

As shown in FIG. 2, in sub-block SB0 of block BLK0, memory device 200 can include a select line (e.g., drain select line) 280₀ that can be shared by select circuits 241a, 242a, and 243a. In sub-block SBj of block BLK0, memory device 200 can include a select line (e.g., drain select line) 280ⱼ that can be shared by select circuits 244a, 245a, and 246a. Block BLK0 can include a select line (e.g., source select line) 284 that can be shared by select circuits 241′a, 242′a, 243′a, 244′a, 245′a, and 246′a.

In sub-block SB0 of block BLK1, memory device 200 can include a select line (e.g., drain select line) 280₀. Select line 280₀ of block BLK1 can be shared by select circuits 241b, 242b, and 243b. In sub-block SBj of block BLK1, memory device 200 can include a select line (e.g., drain select line) 280ⱼ that can be shared by select circuits 244b, 245b, and 246b. Select lines 280₀ and 280ⱼ of block BLK1 are electrically separated from select lines 280₀ and 280ⱼ of block BLK0. Block BLK1 can include a select line (e.g., source select line) 284 that can be shared by select circuits 241′b, 242′b, 243′b, 244′b, 245′b, and 246′b.

FIG. 2 shows an example where memory device 200 includes one drain select line (e.g., select line 280₀) shared by select circuits (e.g., select circuits 241a, 242a, or 243a) in a sub-block (e.g., sub-block SB0 of block BLK0). However, memory device 200 can include multiple drain select lines shared by select circuits in a sub-block. FIG. 2 shows an example where memory device 200 includes one source select line (e.g., select line 284) shared by source select circuits (e.g., select circuits 241′a, 242′a, or 243′a) in a sub-block (e.g., sub-block SB0 of block BLK0). However, memory device 200 can include multiple source select lines shared by source select circuits in a sub-block.

In FIG. 2, each of the drain select circuits of memory device 200 can include a drain select gate (e.g., a transistor, shown in FIG. 3A) between a respective data line and a respective memory cell string. The drain select gate (e.g., transistor) can be controlled (e.g., turned on or turned off) by a signal on the respective drain select line based on voltages provided to the signal.

In FIG. 2, each of the source select circuits of memory device 200 can include a source select gate (e.g., a transistor, shown in FIG. 3A) coupled between source 290 and a respective memory cell string. The source select gate (e.g., transistor) can be controlled (e.g., turned on or turned off) by a signal on a respective source select line based on a voltage provided to the signal.

FIG. 3A shows a detailed schematic diagram including blocks of the blocks BLK0 and BLK1 of memory device 200 of FIG. 2, according to some embodiments described herein. In FIG. 3A, directions X, Y, and Z in FIG. 3A can be relative to the physical directions (e.g., three dimensional (3D) dimensions) of the structure of memory device 200. For example, the Z-direction can be a direction perpendicular to (e.g., vertical direction with respect to) a substrate of memory device 200 (e.g., a substrate 599 shown in FIG. 5A). The Z-direction is perpendicular to the X-direction and Y-direction (e.g., the Z-direction is perpendicular to an X-Y plane of memory device 200).

For simplicity, only some of the memory cell strings and some of the select circuits of memory device 200 of FIG. 2 are labeled in FIG. 3A. As shown in FIG. 3A, each select line can carry an associated separate select signal. For example, in sub-block SB0 of block BLK0, select line (e.g., drain select line) 280₀ can carry signal (e.g., drain select-gate signal) SGD0₀. In sub-block SBj of block BLK0, select line (e.g., drain select line) 280ⱼ can carry signal (e.g., drain select-gate signal) SGD0ⱼ. Sub-blocks SB0 and SBj of block BLK0 can share select line 284 that can carry signal (e.g., source select-gate signal) SGS0.

In sub-block SB0 of block BLK1, select line (e.g., drain select line) 280₀ can carry signal (e.g., drain select-gate signal) SGD1₀. In sub-block SBj of block BLK1, select line (e.g., drain select line) 280ⱼ can carry signal (e.g., drain select-gate signal) SGD1ⱼ. Sub-blocks SB0 and SBj of block BLK1 can share select line 284 that can carry signal (e.g., source select-gate signal) SGS1.

For simplicity, similar or the same elements in the memory devices (e.g., memory device 200) described herein are given the same label. For example, as shown in FIG. 3A, similar drain select lines (and their associated signals) are given the same labels for simplicity. However, as shown in FIG. 3A, the drain select lines (from the same block or from different blocks) of memory device 200 are electrically separated from each other and carry different signals (although the signals are given the same labels).

As shown in FIG. 3A, memory device 200 can include memory cells 210, 211, 212, and 213; select gates (e.g., drain select gates or transistors) 260; and select gates (e.g., source select gates) 264 that can be physically arranged in three dimensions (3D), such as X, Y, and Z directions (e.g., dimensions), with respect to the structure (shown in FIG. 4) of memory device 200.

In FIG. 3A, each of the memory cell strings (e.g., memory cell string 231a) of memory device 200 can include series-connected memory cells that include one of memory cells 210, one of memory cells 211, one of memory cells 212, and one of memory cells 213. FIG. 3A shows an example of four memory cells 210, 211, 212, and 213 in each memory cell string. The number of memory cells in each memory cell string can vary. For example, each memory string can include up to hundreds (or more) of memory cells.

As shown in FIG. 3A, memory device 200 can include conductive connections 260C coupled between respective select gates 260 and respective data lines memory cells to respective data lines 270₀ through 270_{N}. In the physical structure of memory device 200, each conductive connection 260C is part of a contact structure (e.g., contact structure 560 in FIG. 5A) associated with a memory cell pillar (e.g., pillar 550 in FIG. 5A) of memory device 200.

As shown in FIG. 3A, each drain select circuit (e.g., select circuit 241a) can include one of select gates 260. Each source select circuit (e.g., select circuit 241′a) can include one of select gates 264.

Each select gate 260 in FIG. 3A can operate like a transistor. For example, select gate 260 of select circuit 241a can operate like a field effect transistor (FET), such as a metal-oxide semiconductor FET (MOSFET). An example of such a MOSFET include an n-channel MOS (NMOS) transistor.

A select line (e.g., select line 280₀ of sub-block SB0 of block BLK0) can carry a signal (e.g., signal SGD0₀) but it does not operate like a switch (e.g., a transistor). A select gate (e.g., select gate 260 of select circuit 241a) can receive a signal (e.g., signal SGD0₀) from a respective select line (e.g., select line 280₀ of sub-block SB0 of block BLK0) and can operate like a switch (e.g., a transistor).

In the physical structure of memory device 200, a select line (e.g., select line 280₀ of sub-block SB0 of block BLK0) can be a structure (e.g., a level) of a conductive material (e.g., a layer (e.g., a piece) or a region of conductive material) located in a single level of memory device 200. The conductive material can include metal, doped polysilicon, or other conductive materials.

In the physical structure of memory device 200, a select gate (e.g., select gate 260 of select circuit 241a of sub-block SB0 of block BLK0) can include (can be formed from) a portion of the conductive material of a respective select line (e.g., select line 280₀ of sub-block SB0 of block BLK0), a portion of a channel material (e.g., polysilicon channel), and a portion of a dielectric material (e.g., similar to a gate oxide of a transistor [e.g., FET]) between the portion of the conductive material and the portion of the channel material.

In this description, a material can include a single material (e.g., a single layer of material) or a combination of multiple materials (e.g., multiple layers of material). For example, a conductive material can include a single conductive material (e.g., a single layer of conductive material) or a combination of multiple conductive materials (e.g., multiple layers of different conductive materials). In another example, a dielectric material can include a single dielectric material (e.g., a single layer of dielectric material) or a combination of multiple dielectric materials (e.g., multiple layers of different dielectric materials).

FIG. 3A shows an example where memory device 200 includes one drain select gate (e.g., select gate 260) in each drain select circuit, and one source select gate (e.g., select gate 264) in each source select circuit coupled to a memory cell string. However, memory device 200 can include multiple drain select gates (e.g., multiple select gates 260 connected in series) in each drain select circuit, multiple source select gates (e.g., multiple select gates 264 connected in series) in each source select circuit, or both multiple drain select gates and multiple source select gates coupled to a memory cell string.

FIG. 3B shows an example of memory device 200 including four select gates (e.g., four drain select gates) 260_{A}, 260_{B}, 260_{C}, and 260_{D} associated with four select lines 280_{A}, 280_{B}, 280_{C}, and 280_{D}. Memory device 200 can use signals SGD_{A}, SGD_{B}, SGD_{C}, and SGD_{D} on select lines 280_{A}, 280_{B}, 280_{C}, and 280_{D}, respectively, to control (turn on or turn off) select gates 260_{A}, 260_{B}, 260_{C}, and 260D, respectively. Data line 270 and associated signal BL can be one of data lines 270₀ through 270_{N} associated with one of signals BL₀ through BL_{N}, respectively. Memory cell string 231 and associated conductive connection 260C can be one of the memory cell strings (e.g., memory cell string 231a) associated with conductive connection 260C of memory device 200 of FIG. 3A.

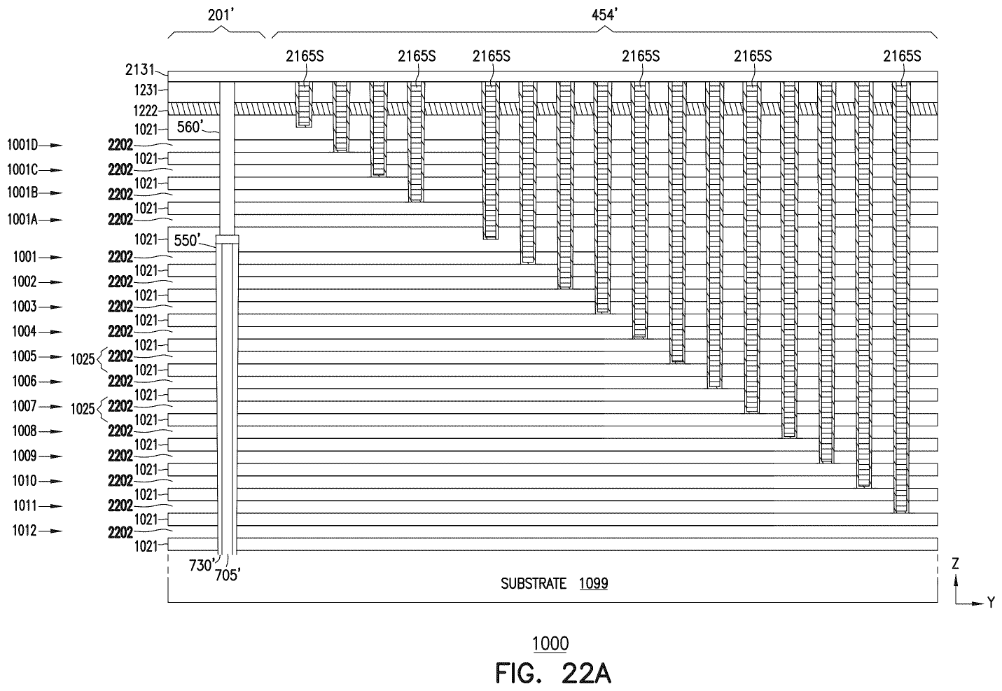

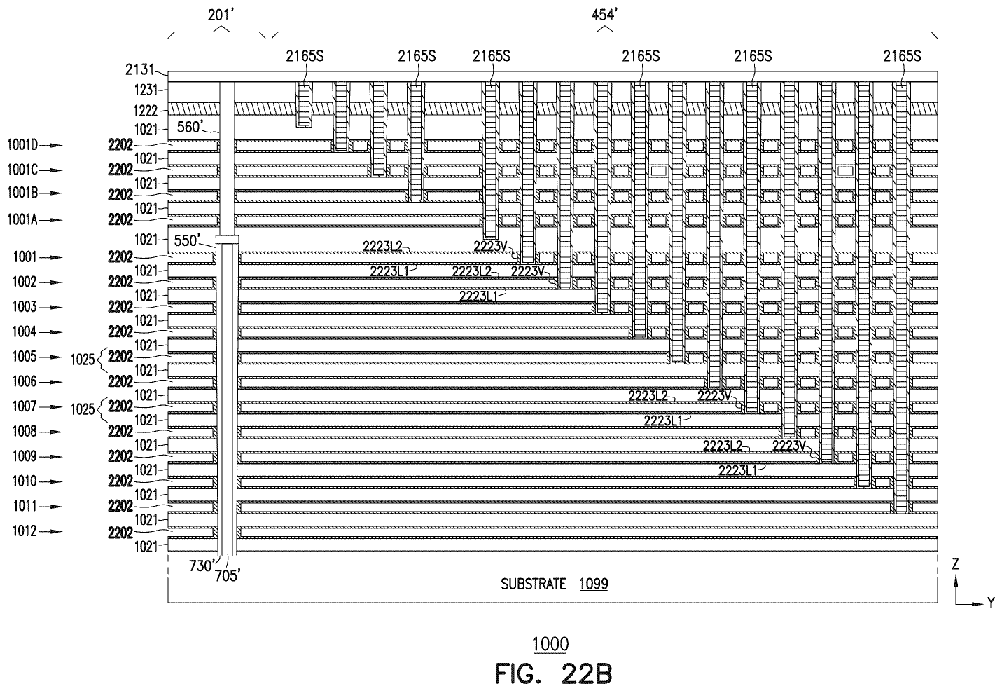

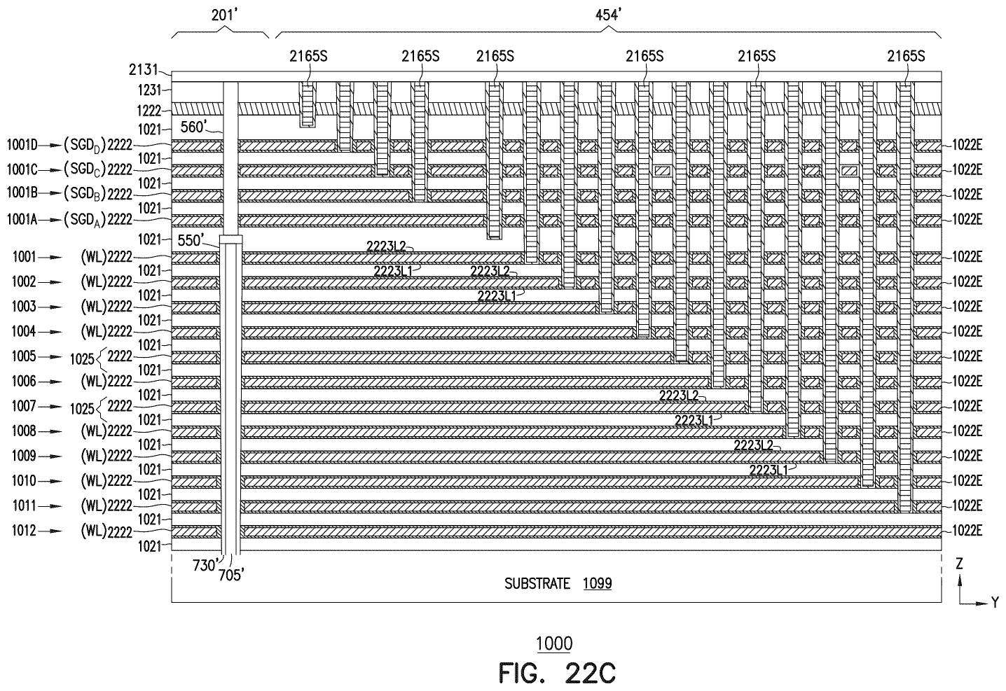

The structures of select lines 280_{A}, 280_{B}, 280_{C}, and 280_{D} can be similar to or the same as those of the select lines associated with signals SGD_{A}, SGD_{B}, SGD_{C}, and SGD_{D} of memory device 1000 in FIG. 22. FIG. 3B shows one source select gate (e.g., select gate 264) and one source select signal (e.g., signal SGS0) on a source select line (e.g., select line 284). However, memory device 200 can include two or more source select gates (in the Z-direction) like select gates 260_{A}, 260_{B}, 260_{C}, and 260_{D}.

FIG. 4 shows a top view of a structure of a portion of memory device 200 of FIG. 2 and FIG. 3A including a region of memory array 201 including blocks BLK0 and BLK1, structures 451 between blocks, data lines extending over blocks BLK0 and BLK1, and a region 454, according to some embodiments described herein.

For simplicity, some elements of memory device 200 (and other memory devices described herein) may be omitted from a particular figure of the drawings so as not to obscure the view or the description of the element (or elements) being described in that particular figure. Also, for simplicity, cross-sectional lines (e.g., hatch lines) are omitted from some or all the elements shown in the drawings described herein. Some elements of memory device 200 may be omitted from a particular figure of the drawings so as not to obscure the view or the description of the element (or elements) being described in that particular figure. Further, the dimensions (e.g., physical structures) of the elements of memory device 200 (and other memory devices) in the drawings described herein are not scaled. Moreover, the description of the same elements described with reference to one figure may not be repeated in the description with reference another figure. For example, the description of the same elements of memory device 200 described above with reference to FIG. 2, FIG. 3A, and FIG. 3B may not be repeated in the description with reference another figure (e.g., FIG. 4 and other figures).

In FIG. 4, structures 451 can be formed to separate (physically separate) one block and another block of memory device 200. Two adjacent blocks (e.g., blocks BLK0 and BLK1) can be separated from each other by one of structures 451. Each structure 451 can have a length in the Y-direction. Each structure 451 can include a dielectric material (e.g., silicon dioxide) or a combination of a dielectric material and additional material (e.g., a non-conductive material). Each structure 451 can include a slit (not labeled) and materials (not labeled) formed in (e.g., filled in) the slit. The slit can include (or can be part of) a trench between adjacent blocks (e.g., blocks BLK0 and BLK1. Structures 451 can be called a dielectric structure or a slit structure. The regions of memory device 200 at which structures 451 are located can be called slit regions.

As shown in FIG. 4, block BLK0 can include sub-blocks (e.g., four sub-blocks) SB0, SB1, SB2, and SB3 and select lines (e.g., four drain select lines) associated with signals SGD0₀, SGD1₀, SGD2₀, and SGD3₀, respectively. Signals SGD0₀, SGD1₀, SGD2₀, and SGD3₀ can correspond to some of signals SGD0₀ through SGD0ⱼ in FIG. 3A. In FIG. 4, the select lines can include respective conductive regions (e.g., conductive materials) that are electrically separated from each other (in the X-direction) and can be located on the same level (with respect to the Z-direction). The select lines associated with signals SGD0₀, SGD1₀, SGD2₀, and SGD3₀ can be located over (with respect to the Z-direction) the control gates (under the select lines) of block BLK0. As shown in FIG. 4, each of the select lines (associated with signals SGD0₀, SGD1₀, SGD2₀, and SGD3₀) can have length in the Y-direction from memory array 201 to region 454. FIG. 4 shows an example where each block of memory device 200 can have four sub-blocks SB0, SB1, SB2, and SB3. However, the number of sub-blocks can be different from four.

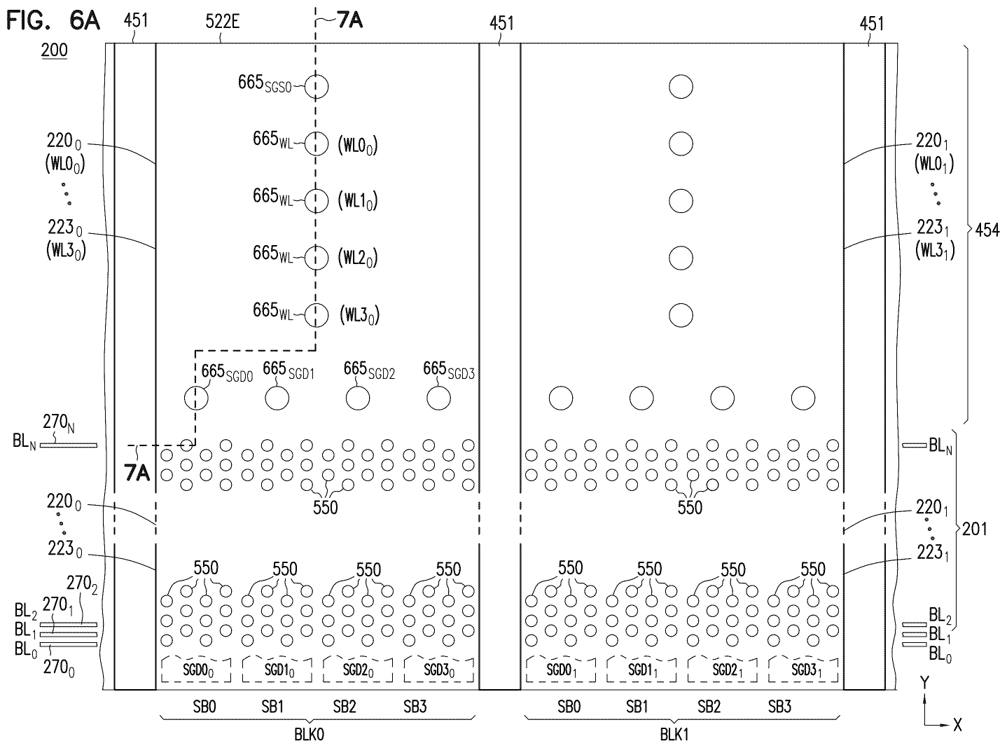

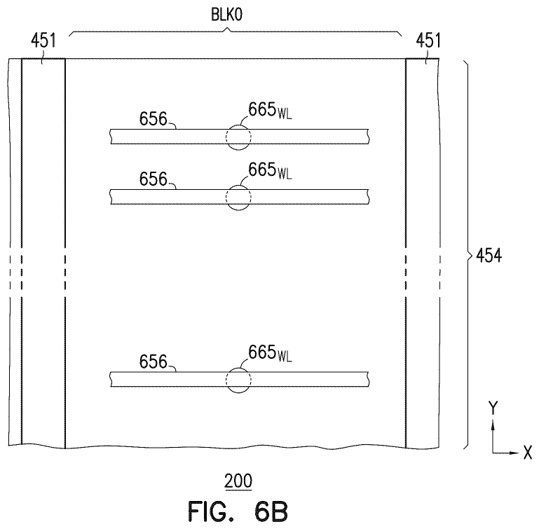

Block BLK1 can have a structure like block BLK0. As shown in FIG. 4, block BLK1 can include sub-blocks SB0, SB1, SB2, and SB3 and select lines (e.g., drain select lines) associated with signals SGD01, SGD11, SGD21, and SGD31 (which can correspond to some of signals SGD1₀ through SGD1ⱼ in FIG. 3A). As described below with reference to FIG. 6A, region 454 can be a location where conductive contacts associated with control gates (e.g., control gates 220₀, 221₀, 222₀, and 223₀ and control gates 220₁, 221₁, 222₁, and 223₁ in FIG. 3A) of memory device 200 can be formed.

A side view (e.g., cross-section) at memory array (memory cell array) 201 of memory device 200 along line 5A-5A in FIG. 4 is shown in FIG. 5A.

FIG. 5A shows a side view (e.g., cross-section) of a structure of a portion of memory device 200 of FIG. 4 including tiers (tiers of materials) 525 that include respective memory cells (e.g., tiers of memory cells) and control gates (e.g., tiers of control gates) associated with (e.g., to control) the memory cells, according to some embodiments described herein. FIG. 5A also partially shows other blocks (on the left and right sides of blocks BLK0 and BLK1) of memory device 200. FIG. 5A shows an example of four tiers of memory cells associated with four control gates (associated with signals WL0, WL1, WL2, and WL3). However, memory device 200 can include up to hundreds of tiers of memory cells (or more than hundreds of tiers of memory cells). The number of tiers of memory cells can be the same as the number of the control gates (tiers of control gates).

As shown in FIG. 5A, memory device 200 can include a substrate 599, source 290 formed over substrate 599, and different levels 501 through 512 over substrate 599 in the Z-direction. Levels 501 through 512 are physical device levels of memory device 200 over substrate 599. Memory device 200 can include a dielectric material 581 formed over at least a portion of memory device 200. Memory cells 210, 211, 212, and 213 of the memory cell strings (e.g., memory cell string 231a in FIG. 3A) of respective sub-blocks SB0, SB1, SB3, and SB3 of each of blocks BLK0 and BLK1 can be formed over substrate 599 and source 290 (e.g., formed vertically in Z-direction in respective levels among levels 501 through 512).

As shown in FIG. 5A, data line 2701 (associated with signal BL1) can extend in the X-direction across the blocks (e.g., blocks BLK0 and BLK1 and other blocks) of memory device 200. Data line 2701 can be shared by respective memory cell strings (including memory cell string 231a) of the blocks.

In FIG. 5A, the select lines (e.g., four drain select lines in the X-direction) indicated by signal SGD can correspond to respective select lines (e.g., drain select lines) of a respective block of blocks BLK0 and BLK1. For example, in sub-blocks SB0, SB1, SB2, and SB3 of block BLK0, the select lines (e.g., four drain select lines) indicated by signal SGD can correspond to respective select lines associated with signals SGD0₀, SGD1₀, SGD2₀, and SGD3₀ of block BLK0 shown in FIG. 4. In another example, in sub-blocks SB0, SB1, SB2, and SB3 of block BLK1, the select lines (e.g., four drain select lines in the X-direction) indicated by signal SGD can correspond to respective select lines associated with signals SGD01, SGD11, SGD21, and SGD31 of block BLK1 shown in FIG. 4.

As shown in FIG. 5A, the select lines (e.g., four drain select lines) in the same block (e.g., block BLK0) can include respective conductive regions (e.g., four conductive regions) that are electrically separated from each other and can be located on the same level (e.g., level 512) in the Z-direction of memory device 200 and located over the control gates (in the Z-direction) of the respective block.

The select lines (e.g., source select lines) indicated by signal SGS (on level 501) can correspond to respective select lines of blocks BLK0 and BLK1. For example, in block BLK0, the select line indicated by signal SGS can correspond to the select line (e.g., source select line) associated with signals SGS0 of block BLK0 shown in FIG. 3A. In another example, in block BLK1, the select line indicated by signal SGS can correspond to the select line (e.g., source select line) associated with signals SGS1 of block BLK1 shown in FIG. 3A.

In FIG. 5A, for simplicity, control gates (e.g., four control gates) of blocks BLK0 and BLK1 are indicated by the same signals WL0, WL1, WL2, and WL3. For example, in block BLK0, the control gates indicated by signals WL0, WL1, WL2, and WL3 can correspond to respective control gates associated with signals WL0₀, WL1₀, WL2₀, and WL3₀, respectively, of block BLK0 shown in FIG. 3A. In another example, in block BLK1 in FIG. 5A, the control gates indicated by signals WL0, WL1, WL2, and WL3 can correspond to respective control gates associated with signals WL0₁, WL1₁, WL2₁, and WL3₁, respectively, of block BLK1 shown in FIG. 3A.

As shown in FIG. 5A, memory device 200 can include dielectric materials (e.g., silicon dioxide) 521 located on levels 503, 505, 507, 509, and 511. Dielectric materials 521 in a respective block are interleaved with conductive materials 522. Conductive materials 522 can form part of respective control gates (associated with signals WL0, WL1, WL2, and WL3) in the respective block. As shown in FIG. 5A, dielectric materials 521 can be located on respective levels among levels 501 through 512. Conductive materials 522 can be located on respective levels (e.g., levels 502, 504, 506, 508, 510, and 512) among levels 501 through 512 that are interleaved with the levels of dielectric materials 521. Examples of conductive materials 522 (which form the control gates) include a single conductive material (e.g., single metal, e.g., tungsten) or a combination of different layers of conductive materials. For example, each of the control gates of blocks BLK0 and BLK1 can include (e.g., multi-layers of) aluminum oxide, titanium nitride, tungsten.

As shown in FIG. 5, dielectric materials 521 can form levels of dielectric materials 521. Conductive materials 522 can form levels of conductive materials 522 that are interleaved with levels of dielectric materials 521. The levels of dielectric materials 521 and the levels of conductive materials 522 can form tiers 525 of memory device 200. Each tier 525 can include a level of dielectric material 521 and a level of conductive material 522. The level of dielectric material (e.g., silicon dioxide) 521 in respective tier 525 can be called tier oxide.

For simplicity, only some of tiers 525 are labeled in FIG. 5A. As shown in FIG. 5A, tiers 525 can be located one over another and can include respective levels of memory cells 210, 211, 212, and 213, and control gates associated with the memory cells. FIG. 5A shows a few tiers (e.g., only two tiers 525 are labeled) of memory device 200 as an example. However, memory device 200 can include up to hundreds of tiers (or more than hundreds of tiers).

As shown in FIG. 5A, memory device 200 can include pillars (memory cell pillars) 550 in blocks BLK0 and BLK1. Each of pillars 550 can be part of a respective memory cell string (e.g., memory cell string 231a). Each of pillars 550 can have length extending through at least a portion of the levels of dielectric materials 521 and the levels of conductive materials 522 (associated with tiers of memory cells) in the Z-direction (e.g., extending vertically in the direction of the Z-direction) from substrate 599 between substrate 599 and data line 2701. As shown in FIG. 5A, the Z-direction is also a direction at which the length of pillar 550 extends from one tier to another tier, which is also a direction from levels of dielectric materials 521 to levels of conductive materials 522.

As shown in FIG. 5A, memory device 200 can include contact structures (e.g., data line contact structures) 560. Each pillar 550 can be coupled to a data line by a respective contact structure 560. Each contact structure 560 can be considered as part of a respective pillar 550 and can include a conductive material (or conductive materials) to allow electrical signal between pillar 550 and a respective data line.

As shown in FIG. 5A, memory cells 210, 211, 212, and 213 of respective memory cell strings (e.g., memory cell string 231a) can be located in different levels (e.g., levels 504, 506, 508, and 510) in the Z-direction of memory device 200. The control gates (associated with signals WL0, WL1, WL2, and WL3) of each of blocks BLK0 and BLK1 can be located on the same levels (e.g., levels 504, 506, 508, and 510) at which memory cells 210, 211, 212, and 213 are located. Thus, memory cells 210, 211, 212, and 213 and the control gates of blocks BLK0 and BLK1 can be located (e.g., vertically located) along respective portions (e.g., portions on levels 504, 506, 508, and 510) of pillars 550 in the Z-direction.

Substrate 599 of memory device 200 can include monocrystalline (also referred to as single-crystal) semiconductor material. For example, substrate 599 can include monocrystalline silicon (also referred to as single-crystal silicon). The monocrystalline semiconductor material of substrate 599 can include impurities, such that substrate 599 can have a specific conductivity type (e.g., n-type or p-type).

As shown in FIG. 5A, memory device 200 can include circuitry 595 located in (e.g., formed in) substrate 599. At least a portion of the circuitry 595 can be located in a portion of substrate 599 that is under (e.g., directly under) memory cell strings of blocks BLK0 and BLK1. Circuitry 595 can include transistors (e.g., Tr1 and Tr2) that can be part of decoder circuits, driver circuits (e.g., word line drivers), buffers, sense amplifiers, charge pumps, and other circuitry of memory device 200.

In FIG. 5A, source 290 can include a conductive material (or materials, e.g., different levels of different materials) and can have a length extending in the X-direction. FIG. 5A shows an example where source 290 can be formed over a portion of substrate 599 (e.g., by depositing a conductive material over substrate 599). Alternatively, source 290 can be formed in or formed on a portion of substrate 599 (e.g., by doping a portion of substrate 599).

The select lines (associated with signals SGS and SGD) of blocks BLK0 and BLK1 can have the same material (or materials) as the control gates (associated with signals WL0, WL1, WL2, and WL3) of blocks BLK0 and BLK1. Alternatively, the select gates associated with signal SGS, SGD, or both have material (or materials) different from the material of the control gates.

FIG. 5B shows an example structure of memory device 200 of FIG. 5A including four select gates (e.g., four drain select gates) 260_{A}, 260_{B}, 260_{C}, and 260_{D} associated with a memory cell string (e.g., memory cell string 231). The other elements of memory device 200 of FIG. 5B can be the same as those of memory device 200 shown in FIG. 5A. Memory device 200 of FIG. 5B can represent the structure of memory device 200 that is schematically shown in FIG. 3B. FIG. 5B shows an example of memory device 200 including four select gates (e.g., four drain select gates) associated with signals SGD_{A}, SGD_{B}, SGD_{C}, and SGD_{D}. Conductive materials 522 on respective levels 512′, 513′, 514′, and 515′ form the select lines (e.g., four select lines) associated with the select gates. Like memory device 200 of FIG. 5A, memory device 200 of FIG. 5B can include contact structures (e.g., data line contact structures) 560 associated with pillars (memory cell pillars) 550.

FIG. 6A shows a top view of a structure of memory device 200 of FIG. 4, according to some embodiments described herein. FIG. 6B shows a top view of additional elements of memory device 200 of FIG. 6A, according to some embodiments described herein. As shown in FIG. 6A, pillars 550 (shown in top view) can be located in the region included in memory array 201, which is adjacent region 454. Region 454 can be called conductive contact region (e.g., word line conductive contact region) of memory device 200. FIG. 6A, control gates 220₀ through 223₀ are located one over another (stacked in tiers 525 shown in FIG. 5A). Each of control gates 220₀ through 223₀ can extend from region memory array 201 to region 454.

As shown in FIG. 6A, in region 454, memory device 200 can include conductive contacts (e.g., word line contacts) 665_{WL}, conductive contacts (e.g., drain select line contacts) 665_{SGDO}, 665_{SGD1}, 665_{SGD2}, and 665_{SGD3}), and conductive (e.g., source select line contact) 665_{SGS0}. Conductive contacts 665_{WL} can include metal (e.g., tungsten or other conductive materials). Although not shown in FIG. 6A for simplicity, memory device 200 can include conductive lines 656 (as shown in FIG. 6B) coupled to respective conductive contacts 665_{WL}.

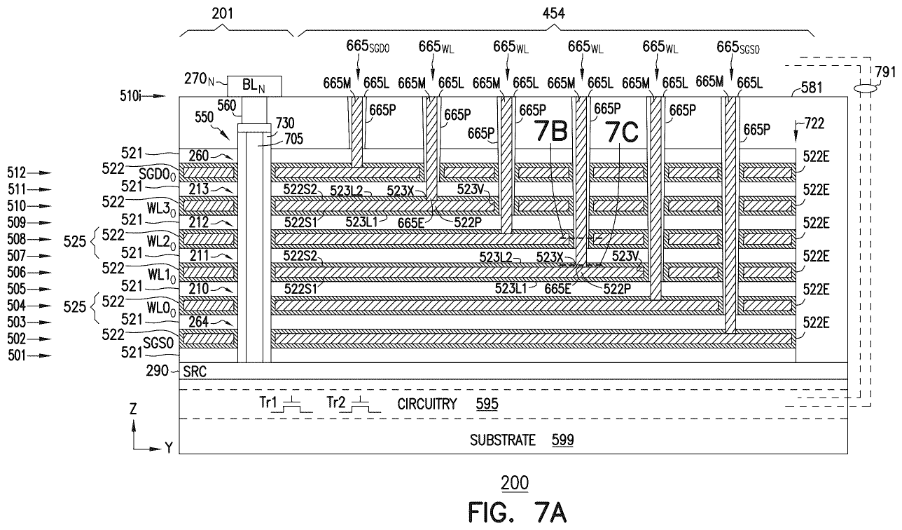

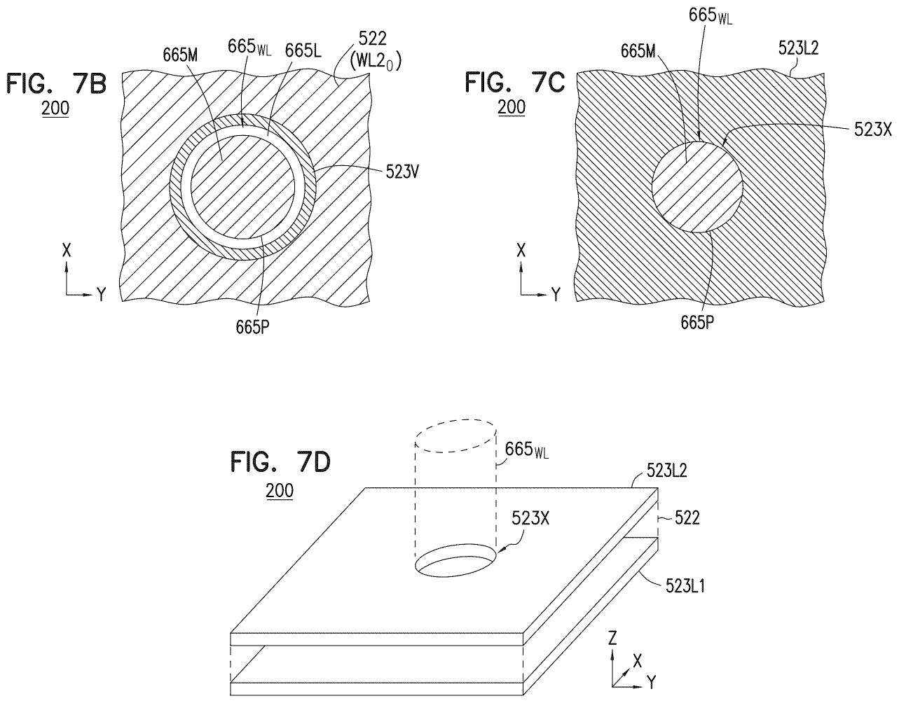

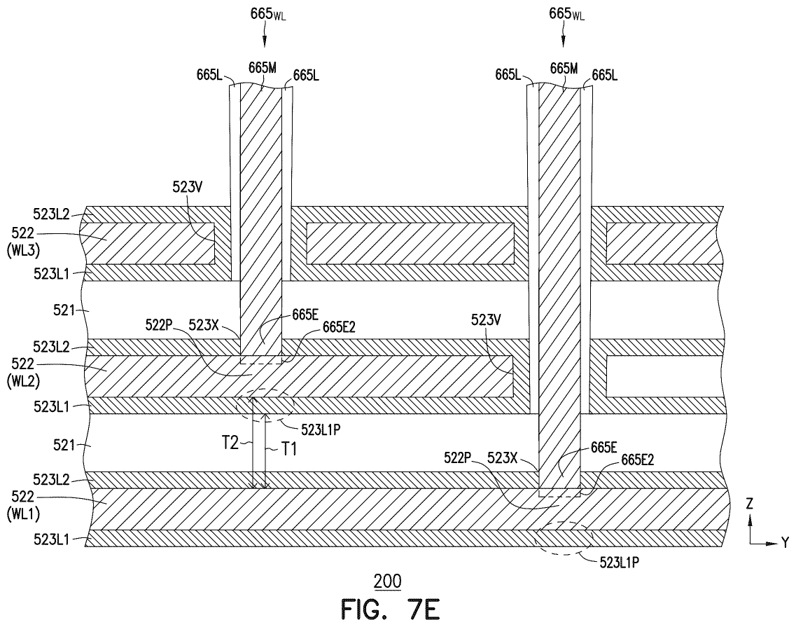

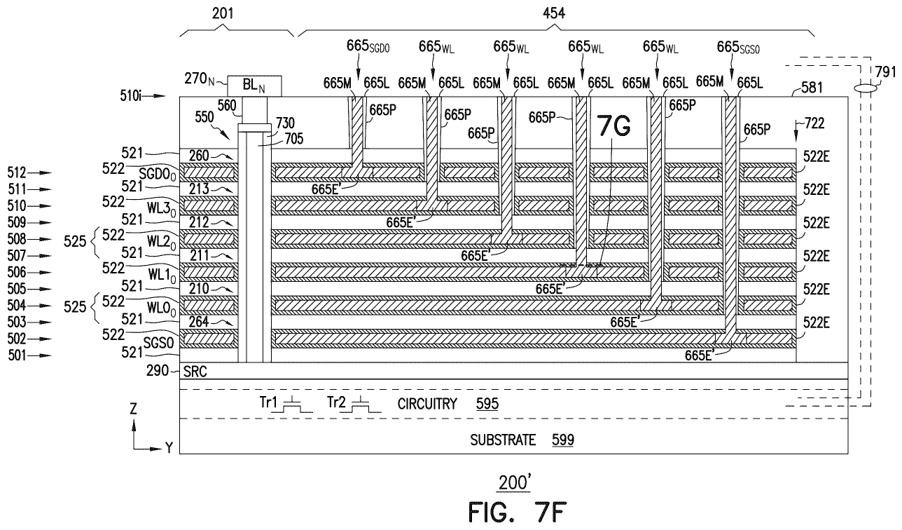

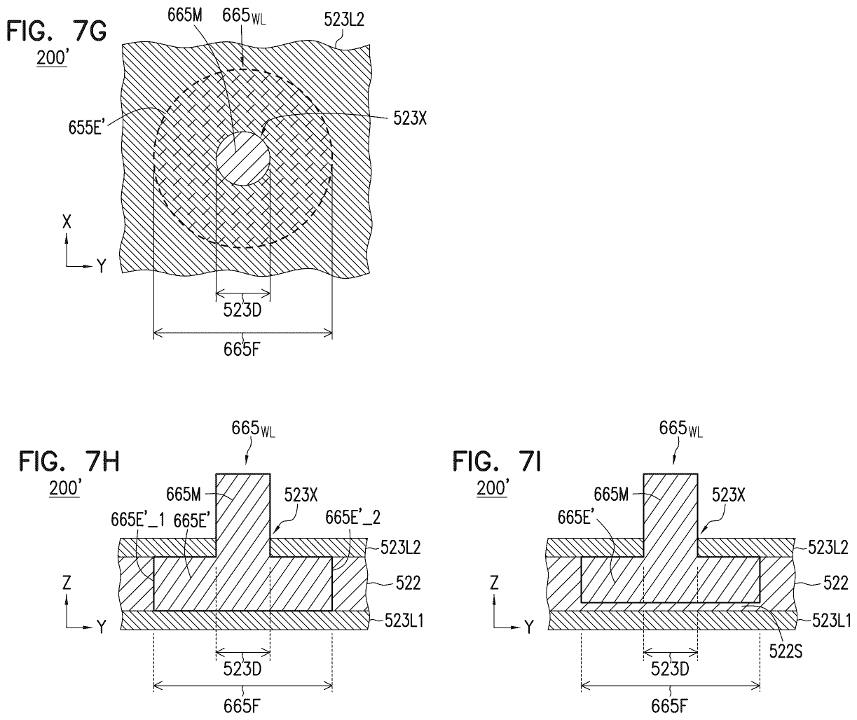

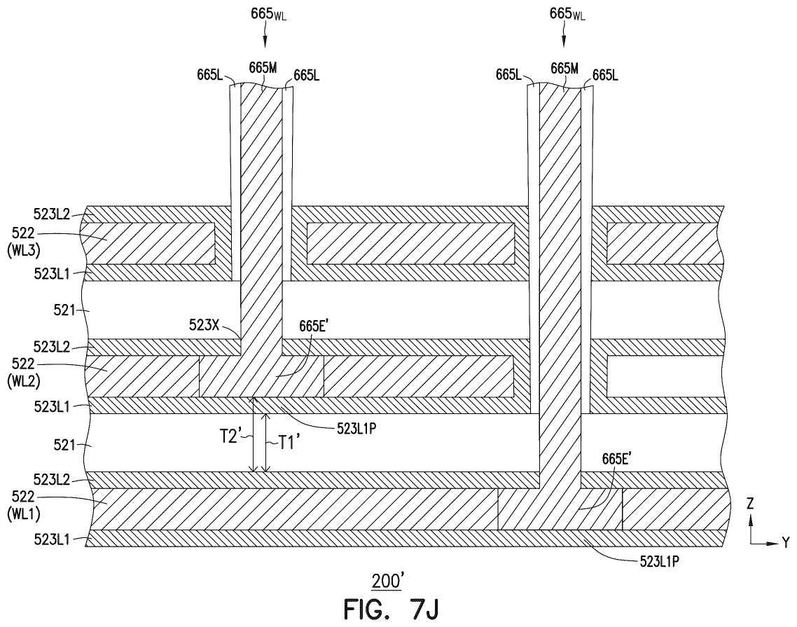

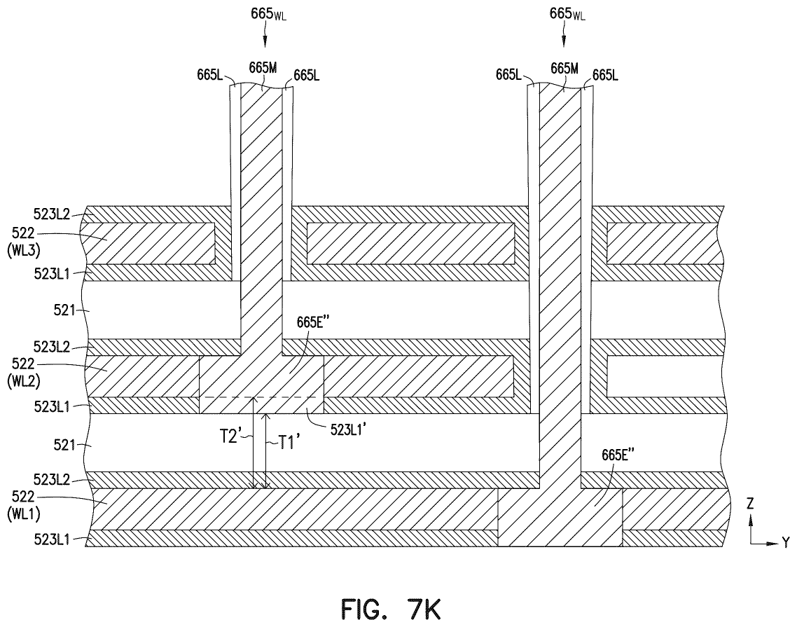

In FIG. 6A, conductive contacts 665_{WL} can contact (form electrical connection with) respective control gates (e.g., control gates 220₀ through 223₀ located under conductive contacts 665_{WL}, hidden from the top view of FIG. 6A). Conductive contacts 665_{WL} can be part of respective access lines (e.g., word lines) of memory device 200. Conductive contacts 665_{WL} allow signals (e.g., signals WL0₀, WL1₀, WL2₀, and WL3₀ in block BLK0 in FIG. 3A) to be provided to respective control gates of block BLK0 through conductive contacts 665_{WL}. FIG. 7A (described in more detail below) shows side views (e.g., cross-sections) of conductive contacts 665_{WL}.

As shown in FIG. 6A, each control gate (associated with one of signals WL0₀, WL1₀, WL2₀, and WL3₀) in block BLK0 of FIG. 6A has an edge 522E. FIG. 7A also shows edges 522E of respective control gates of memory device 200. FIG. 6A shows one edge 522E to indicate that edges 522E (shown in FIG. 7A) may be aligned (e.g., vertically aligned) with each other in the Z-direction and are hidden from the top view of memory device 200 in FIG. 6A.

Similarly, for block BLK1 in FIG. 6A, conductive contacts (e.g., not labeled) can be formed at region 454 to allow signals (e.g., signals WL0₁, WL1₁, WL2₁, and WL3₁ in block BLK1 shown in FIG. 3A) to be provided to respective control gates (e.g., control gates 220₁ through 223₁) of block BLK1 through the conductive contacts at region 454.

In FIG. 6A, select lines associated with signals SGD0₀, SGD1₀, SGD2₀, and SGD3₀ in block BLK0 and signals SGD0₁, SGD1₁, SGD2₁, and SGD3₁ in block BLK1 are partially shown as dotted lines. Each of sub-blocks SB0, SB1, SB2, and SB3 can include multiple rows of pillars 550 associated with a respective select line (one of the select lines associated with signals SGD0₀, SGD1₀, SGD2₀, and SGD3₀). As shown in FIG. 6A, the multiple rows of pillars 550 can be located one after another in the X-direction (rows having lengths parallel to the Y-direction). FIG. 6A shows an example where each sub-block includes four rows of pillars 550. However, the number of rows in the sub-blocks can be less than four or greater than four.

In FIG. 6A, data lines 270₀ through 270_{N} are partially shown for simplicity. Data lines 270₀ through 270_{N} can extend across (in the X-direction) the blocks (e.g., blocks BL0 and BL1). Data lines 270₀ through 270_{N} can be located over and in electrical contact with pillars 550. Contact structures 560 (shown in FIG. 5A or FIG. 5B) coupled between pillars 550 and data lines 270₀ through 270_{N} are not shown in FIG. 6A. Each pillar 550 in the same sub-block of a block can be coupled to a separate (e.g., unique) data line among data lines 270₀ through 270_{N}.

FIG. 6B shows a top view of a portion of memory device 200 including conductive lines 656 associated with block BLK0. For simplicity, only some of conductive lines 656 of memory device 200 are shown in FIG. 6B. Conductive lines 656 can be part of conductive paths (e.g., conductive paths 791 in FIG. 7A) coupled to components (e.g., word line drivers) of circuitry 595 (FIG. 7A) of memory device 200. Conductive lines 656 of a block (e.g., block BLK0) can be formed (e.g., patterned) such that they can be electrically separated from other conductive lines 656 (not shown) of another block (e.g., block BLK1).

A side view (e.g., cross-section) along line 7A-7A in FIG. 6A of block BLK0 is shown in FIG. 7A.

FIG. 7A shows a side view of a portion of memory device 200 including contacts 665_{WL}, 665_{SGDO}, and 665_{SGS0} in region 454, control gates associated with contacts 665_{WL} and signals WL0₀ through WL3₀, and pillar 550 in memory array 201, according to some embodiments described herein. Levels 501 through 512 and tiers 525 of memory device 200 in FIG. 7A are the same as those shown in FIG. 5A. As shown in FIG. 7A, pillar 550 can be located in the portion of memory device 200 that includes memory array 201, which is also shown in top view in FIG. 4 and FIG. 6A. Pillar 550 can extend through conductive materials 522 (which form the control gates and the select lines) and dielectric materials 521 in the portions that include memory array 201.

As shown in FIG. 7A, memory device 200 can include a structure 730 and a dielectric material 705 that can be part of pillar 550. Structure 730 and a dielectric material 705 can extend continuously (in the Z-direction) along the length of the respective pillar 550. Dielectric material 705 can include silicon dioxide. Structure 730 can be electrically coupled to source 290 and a respective data line (e.g., one of data line 270₀ through 270_{N} in FIG. 3A and FIG. 6A). Structure 730 of a respective pillar 550 in a block is adjacent portions of respective control gates of that block. For example, structure 730 of pillar 550 in block BLK0 is adjacent the control gates associated with signals WL0₀, WL1₀, WL2₀, and WL3₀, respectively.

Structure 730 can include a conductive structure that can be part of a conductive path (e.g., pillar channel structure) to conduct current between a respective data line (e.g., one of data line 270₀ through 270_{N} in FIG. 3A and FIG. 6A) coupled to structure 730 and source 290. Structure 730 can also include a material (or materials) that can form a charge storage element (e.g., a memory element) of a respective memory cell (among memory cells 210, 211, 212, and 213) located along a portion of pillar 550. As an example, structure 730 can be part of an ONOS (SiO₂, Si₃N₄, SiO₂, Si) where Si₃N₄ material can form a charge storage element of a respective memory cell, and Si material can be part of the pillar channel structure of pillar 550. In another example, structure 730 can be part of a SONOS (Si, SiO₂, Si₃N₄, SiO₂, Si) structure, a TANOS (TaN, Al₂O₃, Si₃N₄, SiO₂, Si) structure, a MANOS (metal, Al₂O₃, Si₃N₄, SiO₂, Si) structure, or other structures. Alternatively, structure 730 can include a floating gate structure (e.g., polysilicon structure) where the floating gate structure can form a charge storage element of a respective memory (among memory cells 210, 211, 212, and 213) located along a portion of pillar 550.

As shown in FIG. 7A, the control gates associated with signals WL0₀, WL1₀, WL2₀, and WL3₀, and the select lines associated with signals (e.g., drain select signal and source select signal) SGD0₀ and SGS0 can be structured (e.g., patterned), such that they may have the same length in the Y-direction. For example, the control gates (formed from respective conductive materials 522) associated with signals WL1₀, WL2₀, and WL3₀ can have the same length (in the Y-direction) measuring between pillar 550 and edges 522E of respective the control gates. Edges 522E are part of respective conductive materials 522. As shown in FIG. 7A, the control gates associated with signals WL0₀, WL1₀, WL2₀, and WL3₀ can have the same length, such that edges 522E may be aligned (e.g., vertically aligned) with each other at a reference location (e.g., reference point), such as reference location 722 in the X-direction.

Thus, as shown in FIG. 7A, the conductive contacts (e.g., conductive contact 665_{WL}, 665_{SGDO}, and 665_{SGS0}) can be between pillar 550 and edges 522E. For example, the conductive contact 665_{WL} associated with the control gate associated with signal WL1₀ on level 506 is between pillar 550 and edge 522E of conductive material 522 on level 506 and also between pillar 550 and edge 522E of conductive material 522 on level 508 (associated with signal WL2₀).

In another example, the conductive contact 665_{WL} associated with the control gate associated with signal WL2₀ on level 508 is between pillar 550 and edge 522E of conductive material 522 on level 508 and also between pillar 550 and edge 522E of conductive material 522 on level 506 (associated with signal WL1₀).

As shown in FIG. 7A, conductive contacts (e.g., word line contacts) 665_{WL}, conductive contact (e.g., drain select line contact) 665_{SGDO}, and conductive contact (e.g., source select line contact) 665_{SGS0} can include respective pillars (conductive pillars) 665P. Pillars 665P can include different (unequal) lengths extending in the Z-direction. The length of a particular conductive contact 665_{WL} (which is also the length of its associated pillar 665P) can be a distance (the measurement) in the Z-direction from the control gate associated with that particular conductive contact to a reference location (e.g., at level 510i) in memory device 200. For purposes of measuring the lengths of different conductive contacts (e.g., conductive contact 665_{WL}) in this description, the same reference location (e.g., at level 510i) with respect to the Z-direction is used for the length measurement.

For example, as shown in FIG. 7A, level 510 is the level of the conductive material 522 that forms the control gate associated with signal WL3₀. Thus, the length of the conductive contact 665_{WL} coupled to the control gate associated with signal WL3₀ can be the distance (the measurement) in the Z-direction from level 510i to level 510. In another example, as shown in FIG. 7A, level 508 is the level of the conductive material 522 that forms the control gate associated with signal WL2₀. Thus, the length of the conductive contact 665_{WL} coupled to the control gate associated with signal WL2₀ can be the distance (the measurement) in the Z-direction from level 510i to level 508.

As shown in FIG. 7A, memory device 200 can include conductive paths (e.g., conductive routings) 791 to form circuit paths between circuitry 595 and other elements of memory device 200. For example, conductive lines 656 (FIG. 6B) associated with the control gates (e.g., control gates associated with signals WL0₀, WL1₀, WL2₀, and WL3₀ in FIG. 7A) of memory device 200 can be part of (or can be coupled to) conductive paths 791. This allows the control gates to couple to circuitry 595 through conductive lines 656 (FIG. 6B) and conductive paths 791 (FIG. 7A). Different views (e.g., cross-sections) along lines 7B and 7C are shown in FIG. 7B and FIG. 7C, respectively.

As shown in FIG. 7A, each conductive contact 665_{WL} can include conductive material 665M (that forms pillar 665P) that extends through (e.g., goes through) respective portions of dielectric materials 521 and conductive materials 522. Each conductive contact (e.g., conductive contact 665_{WL}, 665_{SGDO}, or 665_{SGS0}) can include a portion (e.g., end portion) 665E contacting a respective conductive material 522. Each conductive contact (e.g., conductive contact 665_{WL}, 665_{SGDO}, or 665_{SGS0}) can include a dielectric material 665L. As shown in FIG. 7A, dielectric material 665L can be a relatively thin layer (thin layer of dielectric material). Thus, dielectric material 665L can be called a dielectric liner (e.g., dielectric liner on a vertical side wall of a respective conductive contact, such as conductive contact 665_{WL}).

Dielectric material 665L can be formed to separate (electrically isolate) a respective conductive contact from conductive materials 522 except for one of the conductive material 522 that forms the control gate associated with the conductive contact. For example, conductive contact 665_{WL} that contacts the control gate associated with signal WL1₀ can be separated from the control gates associated with signals WL2₀ and WL3₀ by a dielectric material 665L of conductive contact 665_{WL} that is coupled to the control gates associated with signal WL1₀. Dielectric material 665L can include silicon dioxide or other dielectric materials.

As shown in FIG. 7A, each control gate (e.g., the control gate associated with signal WL1₀) can include a level of conductive material 522, a dielectric liner 523L1 (e.g., horizontal dielectric liner), a dielectric liner 523L2 (e.g., horizontal dielectric liner), and a dielectric liner (e.g., vertical dielectric liner) 523V. Dielectric liners 523L1, 523L2, and 523V can form a dielectric liner structure associated with a respective control gate of memory device 200. Dielectric liner 523L1 and 523L2 and dielectric material (e.g., silicon dioxide) 521 can be part of an electrical isolation between adjacent control gates (e.g., the control gates associated with signals WL0₀, WL1₀, WL2₀, and WL3₀).

As shown in FIG. 7A, dielectric liner 523L1 can be adjacent a side (e.g., bottom side with respect to the Z-direction) 522S1 of a respective conductive material 522. Dielectric liner 523L2 can be adjacent another side (e.g., top side with respect to the Z-direction opposite from the bottom side) 522S2 of the respective conductive material 522. Dielectric liner 523V can be between and coupled to dielectric liners 523L1 and 523L2 at the location adjacent a respective conductive contact.

As shown in FIG. 7A, dielectric liner 523V of a respective control gate can be adjacent (e.g., contacting) dielectric material 665L of a respective conductive contact. For example, dielectric liner 523V of the control gate associated with signal WL3 can be adjacent (e.g., contacting) dielectric material 665L of conductive contact 665_{WL} that is coupled to the control gate associated with signal WL2.

As shown in FIG. 7A, each dielectric liner 523L2 can include an opening 523X on side 522S2 and adjacent (e.g., contacting) a portion 522P of a respective level of conductive material 522. Portion 522P is located adjacent opening 523X in the Z-direction, such that portion 522P can be opposite (e.g., directly opposite) from opening 523X in the Z-direction. As shown in FIG. 7A, conductive material 522 (e.g., portion 522P) of a respective control gate can extend continuously at a region (e.g., contact region) adjacent opening 523X of second dielectric liner 523L2.

As shown in FIG. 7A, a respective conductive contact (e.g., conductive contact 665_{WL}) can extend through (pass through) opening 523X and contact a respective level of conductive material 522 at portion 522P. As shown in FIG. 7A, dielectric liner 523L1 can extend continuously on side 522S1 of portion 522P at a region (e.g., contact region) adjacent opening 523X of second dielectric liner 523L2.

As shown in FIG. 7A, each conductive contact (e.g., conductive contact 665_{WL}) can extend through a number of control gates (e.g., some of control gates associated with signals WL0₀ through WL3₀), a number of levels of dielectric materials 521, and opening 523X of a respective dielectric liner 523L2. For example, as shown in FIG. 7A, the conductive contact 665_{WL} associated with the control gate associated with signal WL1₀ can extend through the control gates associated with signals WL2₀ and WL3₀, dielectric materials 521 on levels 507, 509, and 511, and opening 523X of dielectric liner 523L2 of the control gate associated with signal WL1₀.

As shown in FIG. 7A, dielectric liners 523L1, 523L2, and 523V can form relatively thin layers of dielectric material. Dielectric portions 523L1, 523L2, and 523V can be formed concurrently (e.g., formed simultaneously in the same process step). Thus, dielectric liners 523L1, 523L2, and 523V can have the same dielectric material. An example of a dielectric material for dielectric liners 523L1, 523L2, and 523V includes a high-k dielectric material. Examples of high-k dielectric materials include hafnium oxide (e.g., HfO₂), aluminum oxide (e.g., Al₂O₃), and other high-k dielectric materials. A high-k dielectric material is a dielectric material having a dielectric constant greater than the dielectric constant of silicon dioxide. Alternatively, dielectric liners 523L1, 523L2, and 523V can be formed from a dielectric material (e.g., silicon dioxide) having a dielectric constant less than a dielectric constant of a high-k dielectric material. However, in memory device 200, using a high-k dielectric material (e.g., instead of silicon dioxide) for dielectric liners 523L1, 523L2, and 523V can improve electrical isolation between conductive structures (e.g., between the control gates associated with signals WL0₀ through WL3₀). This improved electrical isolation can lead to improved operations (e.g., read or write operations) of memory device 200.

As shown in FIG. 7A, a conductive material 522 on a respective tier (e.g., one of levels 502, 504, 506, 508, 510, and 512) can be between (e.g., sandwiched between) two respective dielectric liners 523L1 and 523L2 in the respective tier. For example, conductive material 522 of the control gate (associated with signal WL1₀) on level 506 can be between (e.g., sandwiched between) dielectric liners 523L1 and 523L2 on level 506.

FIG. 7B and FIG. 7C show top views (e.g., cross-sections) along lines 7B and 7C, respectively, of FIG. 7A, according to some embodiments described herein. FIG. 7D shows a perspective view of the portion of memory device 200 of FIG. 7C. FIG. 7D shows the level of conductive material 522 (between dielectric liners 523L1 and 523L2) in dash line to improve readability of the elements (e.g., dielectric liners 523L1 and 523L2) in FIG. 7D. As shown in FIG. 7B, conductive material 665M of pillar 665P of conductive contact 665_{WL} can be surrounded by dielectric material 665L and is separated (electrically separated) from conductive material 522 associated with signal WL2₀ by dielectric material 665L. Conductive material 665M is also separated (electrically separated) from conductive material 522 associated with signal WL2₀ by dielectric liner 523V. As shown in FIG. 7C and FIG. 7D, conductive material 665M of pillar 665P of conductive contact 665_{WL} can pass through and is surrounded by opening 523X of dielectric liner 523L2.

FIG. 7E shows an enlarged portion of the structure of memory device 200 of FIG. 7A including the structure of conductive contact 665_{WL} and associated control gates, according to some embodiments described herein. In FIG. 7E, signals WL1, WL2, and WL3 can correspond to those of signals WL1, WL2, and WL3 of FIG. 7A. Other elements in FIG. 7E are the same as those of FIG. 7A.

As shown in FIG. 7E, portion 665E of conductive contact 665_{WL} may not extend (in the Z-direction) into a respective conductive material 522 (e.g., a respective control gate). For example, conductive contact 665_{WL} (e.g., portion 665E of conductive contact 665_{WL}) may stop at a surface (and contact the surface) of a respective conductive material 522. However, conductive contact 665_{WL} may extend at least partially into conductive material 522. For example, conductive contact 665_{WL} may include a portion (e.g., end portion 665E2) that can extend at least partially into conductive material 522.

As shown in FIG. 7E, conductive contact 665_{WL} (e.g., portion 665E or 665E2) does not extend through dielectric liner (e.g., bottom dielectric liner) 523L1 of a respective control gate (e.g., control gate associated with signal WL2). Thus, dielectric liner 523L1 extends continuously (in the Y-direction in FIG. 7E) at a region (e.g., contact region), which is the region where conductive contact 665_{WL} conductive material 522 of the respective control gate. As shown in FIG. 7E, dielectric liner 523L1 extends continuously at the contact region, such that dielectric liner 523L1 includes portion 523L1P between two adjacent control gates (e.g., control gates associated with signals WL1 and WL2).

In FIG. 7E, distance T2 represents the distance between conductive materials 522 of two adjacent control gates (e.g., control gates associated with signals WL1 and WL2). Distance T2 can correspond to (e.g., can be equal) the sum of the thickness (in the Z-direction) of dielectric liner 523L1, the thickness of dielectric material (e.g., silicon dioxide) 521, and the thickness of dielectric liner 523L2.

In an alternative structure (e.g., variation) of memory device 200 (not shown in FIG. 7E), conductive contact 665_{WL} may have a portion (e.g., and end portion similar to portion 665E or 665E2) that may extend (in the Z-direction) into extend through dielectric liner 523L1 and may contact dielectric material 521. In such an alternative structure, dielectric liner 523L1 may not extend continuously (in the Y-direction in FIG. 7E) such that portion 523L1P of dielectric liner 523L1 may be removed (absent from the structure of memory device 200). For example, in the alterative structure, portion 523L1P may be removed (etched away) during the processes of forming conductive contact 665_{WL}, dielectric liner 523L1, or both. In FIG. 7E, distance T1 represents the distance between conductive materials 522 of two adjacent control gates (e.g., control gates associated with signals WL1 and WL2) if portion 523L1P of dielectric liner 523L1 is to be removed in the alternative structure (not shown). Distance T1 can correspond to (e.g., can be equal) the sum of the thickness (in the Z-direction) of dielectric material (e.g., silicon dioxide) 521 and the thickness of dielectric liner 523L2. Thus, distance T2 is greater than distance T1. For example, distance T2 is greater than distance T1 by the thickness (in the Z-direction) of dielectric liner 523L1.

As described above, dielectric liner 523L1 may not be continuously (e.g., when portion 523L1P of dielectric liner 523L1 is removed) in an alternative structure. However, structuring (e.g., forming) memory device 200 as shown in FIG. 7E including a continuous dielectric liner 523L1 (with the presence of portion 523L1P) allows memory device 200 to have improvements and benefits over the alternative structure. For example, the structure of memory device 200 as shown FIG. 7E can improve (e.g., increase) the distance (e.g., from distance T1 to distance T2) between conductive materials 522 of two adjacent control gates (e.g., control gates associated with signals WL1 and WL2) in comparison to an alternative structure in which portion 523L1P is removed. The improved distance (e.g., from distance T1 to distance T2) can improve electrical isolation between two adjacent control gates (e.g., keep breakdown voltage at a target voltage range). This, in turn, can improve operations, performance, and reliability of memory device 200. Further, as shown in FIG. 7E, conductive material 522 of a respective control gate (e.g., control gate associated with signal WL2) can extend continuously at a location adjacent opening 523X. Such a continuity of conductive material 522 can also improve conductivity of the control gate. This can further improve operations and performance of memory device 200.

Memory device 200 can also have improvements and benefits similar to improvements and benefits of memory device 200′ (described in more detail below with reference to FIG. 7J and FIG. 7K) and memory device 1000 (described in more detail below with reference to FIG. 10A through FIG. 26B).

FIG. 7F, FIG. 7G, FIG. 7H, and FIG. 7I show different views of memory device 200′ that can be a variation of memory device 200 of FIG. 2. FIG. 7G, shows a top view (e.g., cross-section) of portion of memory device 200′ at line 7G of FIG. 7F. FIG. 7H shows a side view (e.g., cross-section) of the portion of memory device 200′ of FIG. 7G. FIG. 7I shows a variation of a conductive contact of FIG. 7H. Memory device 200′ in FIG. 7F can include elements that are similar to or the same as the elements of memory device 200 of FIG. 7A. For simplicity, descriptions of similar or the same elements between memory devices 200 and 200′ are not repeated. Differences between memory devices 200 and 200′ include differences in the structure of conductive contact 665_{WL} shown in FIG. 7F, FIG. 7G, and FIG. 7H.

As shown in FIG. 7F, FIG. 7G, and FIG. 7H, conductive contact 665_{WL} memory device 200′ can include a portion (e.g., end portion) 665E′. Unlike portion 665E of memory device 200 of FIG. 7A, portion 665E′ of memory device 200′ has a structure (and associated footprint) that is different from portion 665E of memory device 200 of FIG. 7A. As shown in FIG. 7G and FIG. 7H, portion 665E′ can extend into conductive material 522 at the location adjacent opening 523X of dielectric liner 523L2, such that portion 665E′ can have a dimension 665F that is greater than a dimension 523D of opening 523X of dielectric liner 523L2. Dimension 523D can correspond to a distance (e.g., a diameter) of from one edge to another edge (not labeled) of opening 623X in the Y-direction.

As shown in FIG. 7H, portion 665E′ can have edges (e.g., vertical edges in the Z-direction) 665E′_1 and 665E′_2. Dimension 665F can correspond to the distance (e.g., length of portion 665E′ in the Y-direction) between edges 665E′_1 and 665E′_2 in the Y-direction. As shown in FIG. 7G and FIG. 7H, portion 665E′ can occupy an area (e.g., can have a footprint) in the X-Y plan, such that the footprint (from a top view with respect to the X-Y plane) of portion 665E′ is greater than the footprint (from a top view with respect to the X-Y plane) of opening 523X of dielectric liner 523L2.

As shown in FIG. 7H portion 665E′ can extend into conductive material 522, such that portions 665E′ can contact of dielectric liner 523L1. In an alternative structure of portion 665E′ as shown in FIG. 7I, portion 665E′ can partially extend into conductive material 522, such that portions 665E′ may not contact of dielectric liner 523L1. For example, as shown in FIG. 7I, conductive material 522 can include a portion 522S between portion 665E′ and dielectric liner 523L1, such that portion 665E′ separates portion 665E′ and dielectric liner 523L1 from each other.

FIG. 7J shows an enlarged portion of the structure of memory device 200′ of FIG. 7F including the structure of conductive contact 665_{WL} and associated control gates, according to some embodiments described herein. FIG. 7K shows an example variation of the portion of memory device 200′ of FIG. 7J. In FIG. 7J, signals WL1, WL2, and WL3 can correspond to those of signals WL1, WL2, and WL3 of FIG. 7F. Other elements of memory device 200′ in FIG. 7J are the same as those of FIG. 7F.

As shown in FIG. 7K, in an alternative structure, conductive contact 665_{WL} can include a portion (e.g., an alternative end portion) 665E″ that extends through dielectric liner 523L1 at a location 523L1′. Thus, dielectric liner 523L1 does not extend continuously (in the Y-direction in FIG. 7K) at a region (e.g., contact region) where conductive contact 665_{WL} contacts conductive material 522 of a respective control gate. As shown in FIG. 7K, portion 523L1P (labeled in FIG. 7J) of dielectric liner 523L1 is removed (absent from the structure of memory device 200′).

As shown in FIG. 7J, conductive contact 665_{WL} (e.g., portion 665E′) does not extend through dielectric liner (e.g., bottom dielectric liner) 523L1 of a respective control gate (e.g., control gate associated with signal WL2). Thus, dielectric liner 523L1 extends continuously (in the Y-direction in FIG. 7E) at a region (e.g., contact region), which is the region where conductive contact 665_{WL} conductive material 522 of the respective control gate. As shown in FIG. 7J, dielectric liner 523L1 extends continuously at the contact region, such that dielectric liner 523L1 includes portion 523L1P between two adjacent control gates (e.g., control gates associated with signals WL1 and WL2).

In FIG. 7J, distance T2′ represents the distance between conductive materials 522 of two adjacent control gates (e.g., control gates associated with signals WL1 and WL2). Distance T2′ can correspond to (e.g., can be equal) the sum of the thickness (in the Z-direction) of dielectric liner 523L1, the thickness of dielectric material (e.g., silicon dioxide) 521, and the thickness of dielectric liner 523L2.

In FIG. 7J and FIG. 7K, distance T1′ represents the distance between conductive materials 522 of two adjacent control gates (e.g., control gates associated with signals WL1 and WL2) when portion 523L1P of dielectric liner 523L1 is removed (in the alternative structure of FIG. 7K). As shown in FIG. 7K, distance T1′ can correspond to (e.g., can be equal) the sum of the thickness (in the Z-direction) of dielectric material (e.g., silicon dioxide) 521 and the thickness of dielectric liner 523L2. Thus, thickness T2′ is greater than thickness T1′. For example, distance T2′ is greater than distance D1 by the thickness (in the Z-direction) of dielectric liner 523L1.

As described above, dielectric liner 523L1 may not be continuously (e.g., when portion 523L1P of dielectric liner 523L1 is removed) in an alternative structure in FIG. 7K. However, structuring (e.g., forming) memory device 200′ as shown in FIG. 7J (including conductive contact 665_{WL} and the control gate with a continuous dielectric liner 523L1) allows memory device 200″ to have improvements and benefits over the alternative structure. For example, the structure of memory device 200′ as shown FIG. 7J can improve (e.g., increase) the distance (e.g., from distance T1′ to distance T2′) between conductive materials 522 of two adjacent control gates (e.g., control gates associated with signals WL1 and WL2) in comparison to an alternative structure in which portion 523L1P is removed (FIG. 7K). The improved distance (e.g., from distance T1 to distance T2) can improve electrical isolation between two adjacent control gates (e.g., keep breakdown voltage at a target voltage range). This, in turn, can improve operations, performance, and reliability of memory device 200′. Memory device 200′ can also have improvements and benefits similar to improvements and benefits of memory device 200 described above.

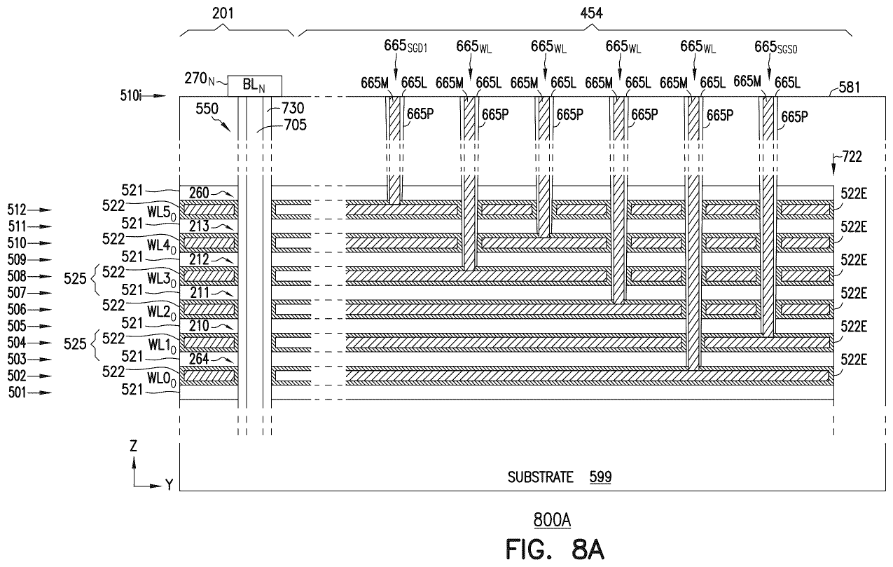

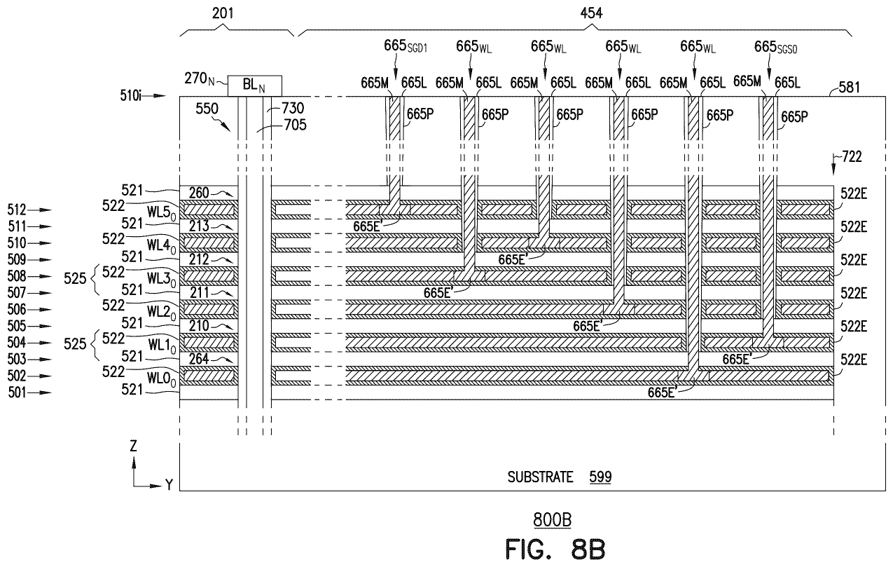

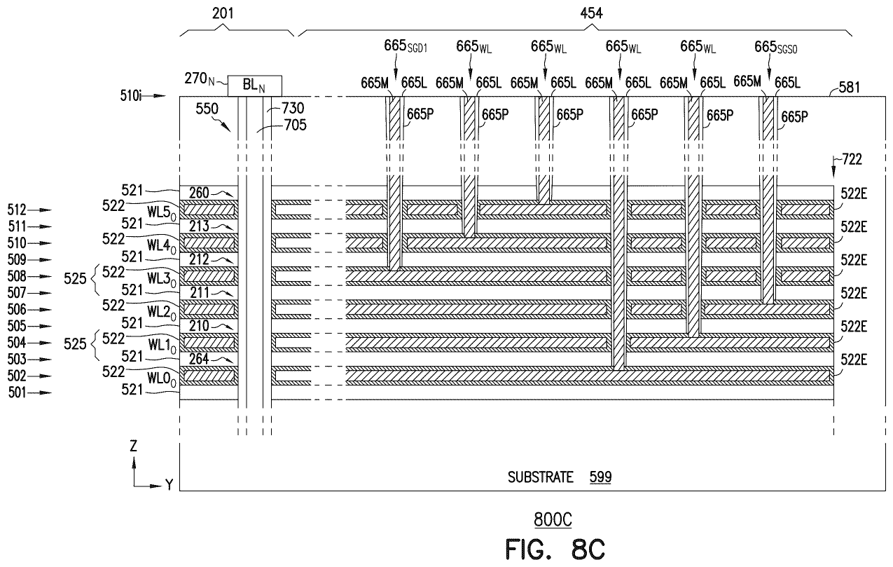

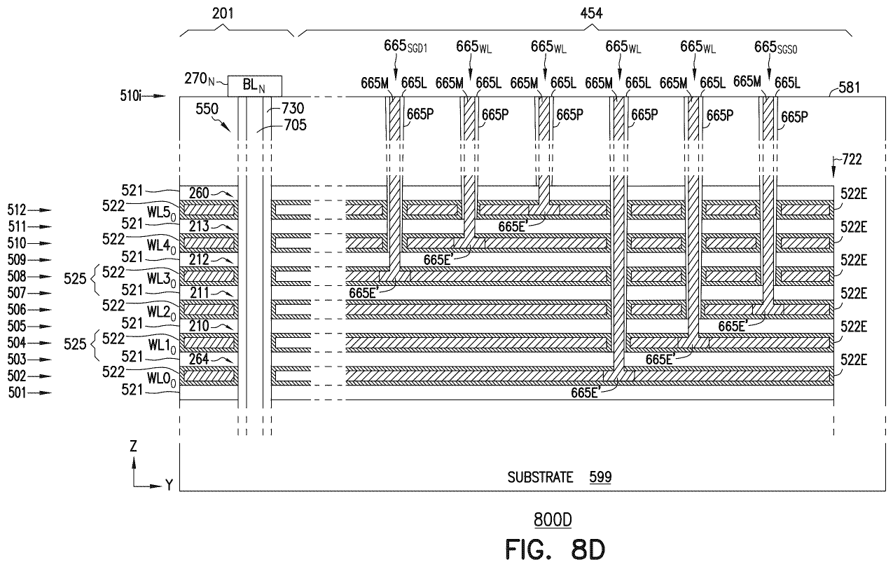

FIG. 8A shows a memory device 800A that can be a variation of memory device 200, according to some embodiments described herein. As shown in FIG. 8A, memory device 800A can include elements that are similar to or the same as the elements of memory device 200. For simplicity, descriptions of similar or the same elements between memory devices 200 and 800A are not repeated.

FIG. 8A shows an example of six conductive contacts coupled to six respective control gates associated with signals WL0₀ through WL5₀. The pattern of the connections between the conductive contacts and the control gates (formed by conductive materials 522) of FIG. 8A is different from that of FIG. 7A. For example, as shown in FIG. 8A, the conductive contact coupled to the control gate associated with signal WL3₀ is between (in the Y-direction) the conductive contact coupled to the control gate associated with signal WL5₀ and the conductive contact coupled to the control gate associated with signal WL40. In this example, the control gate associated with signal WL40 (on level 510 in FIG. 8A) is between (in the Z-direction) the control gate associated with signal WL5₀ (on level 512 in FIG. 8A) and the control gate associated with signal WL3₀ (on level 508 in FIG. 8A).

Further, as shown in FIG. 8A, the length (in the Z-direction) of the conductive contact coupled to the control gate associated with signal WL3₀ is greater than the length of each of the conductive contact coupled to the control gate associated with signal WL5₀ and the conductive contact coupled to the control gate associated with signal WL40. As described above, the length of a particular conductive contact 665_{WL} (which is also the length of its associated pillar 665P) can be a distance from the control gate associated with that particular conductive contact to a reference location (e.g., at level 510i in FIG. 8A) in memory device 200. Improvements and benefits of memory device 800A are similar to or the same as improvements and benefits of devices 200 and 200′ described above.

FIG. 8B show a memory device 800B that can be a variation of memory device 800A, according to some embodiments described herein. As shown in FIG. 8A, memory device 800A can include elements that are similar to or the same as the elements of memory devices 200 (FIG. 7A), 200′ (FIG. 7F), and 800A (FIG. 8A). For simplicity, descriptions of similar or the same elements between memory devices 200, 200′, 800A, and 800B are not repeated. Differences between memory devices 800A and 800B include differences in the structure of conductive contact 665_{WL} in FIG. 8B. As shown in FIG. 8B, conductive contact 665_{WL} can include portion 665E′, which is the same portion 665E′ of memory device 200′ described above with reference to FIG. 7F through FIG. 7I. Improvements and benefits of memory device 800B are similar to or the same as improvements and benefits of memory devices 200 and 200′ described above.

FIG. 8C shows a memory device 800C that can be a variation of memory device 200, according to some embodiments described herein. As shown in FIG. 8C, memory device 800C can include elements that are similar to or the same as the elements of memory device 200. For simplicity, descriptions of similar or the same elements between memory devices 200 and 800C are not repeated. FIG. 8C shows an example of six conductive contacts coupled to six respective control gates associated with signals WL0₀ through WL5₀. The pattern of the connections between the conductive contacts and the control gates (formed by conductive materials 522) of FIG. 8C are different from that of FIG. 7A. For example, as shown in FIG. 8C, the conductive contact coupled to the control gate associated with signal WL3₀ is closer (in the Y-direction) to pillar (memory cell pillar) 550 than the conductive contact coupled to the control gate associated with signal WL40 and the conductive contact coupled to the control gate associated with signal WL5₀. In this example, the length of conductive contact coupled to the control gate associated with signal WL3₀ is greater than the length of each of the conductive contact coupled to the control gate associated with signal WL40 and the conductive contact coupled to the control gate associated with signal WL5₀.

In another example, as shown in FIG. 8C, the conductive contact coupled to the control gate associated with signal WL0₀ is closer (in the Y-direction) to pillar (memory cell pillar) 550 than the conductive contact coupled to the control gate associated with signal WL1₀ and the conductive contact coupled to the control gate associated with signal WL2₀. In this example, the length of the conductive contact coupled to the control gate associated with signal WL0₀ is greater than the length of each of the conductive contact coupled to the control gate associated with signal WL1₀ and the conductive contact coupled to the control gate associated with signal WL2₀. Improvements and benefits of memory device 800C are similar to or the same as improvements and benefits of devices 200 and 200′ described above.

FIG. 8D show a memory device 800D that can be a variation of memory device 800C, according to some embodiments described herein. As shown in FIG. 8A, memory device 800C can include elements that are similar to or the same as the elements of memory devices 200 (FIG. 7A), 200′ (FIG. 7F), and 800C (FIG. 8C). For simplicity, descriptions of similar or the same elements between memory devices 200, 200′, 800C, and 800D are not repeated. Differences between memory devices 800C and 800D include differences in the structure of conductive contact 665_{WL} in FIG. 8D. As shown in FIG. 8D, conductive contact 665_{WL} can include portion 665E′, which is the same portion 665E′ of memory device 200′ described above with reference to FIG. 7F through FIG. 7I. Improvements and benefits of memory device 800D are similar to or the same as improvements and benefits of devices 200 and 200′ described above.

FIG. 7A, FIG. 7F, FIG. 8A, FIG. 8B, FIG. 8C, and FIG. 8D show examples of the patterns of the conductive contacts of memory devices 200, 200′, 800A, 800B, 800C, and 800D, respectively. However, the patterns of the conductive contacts of memory devices 200, 200′, 800A, 800B, 800C, and 800D can be different from those shown in FIG. 7A, FIG. 7F, FIG. 8A, FIG. 8B, FIG. 8C, and FIG. 8D.

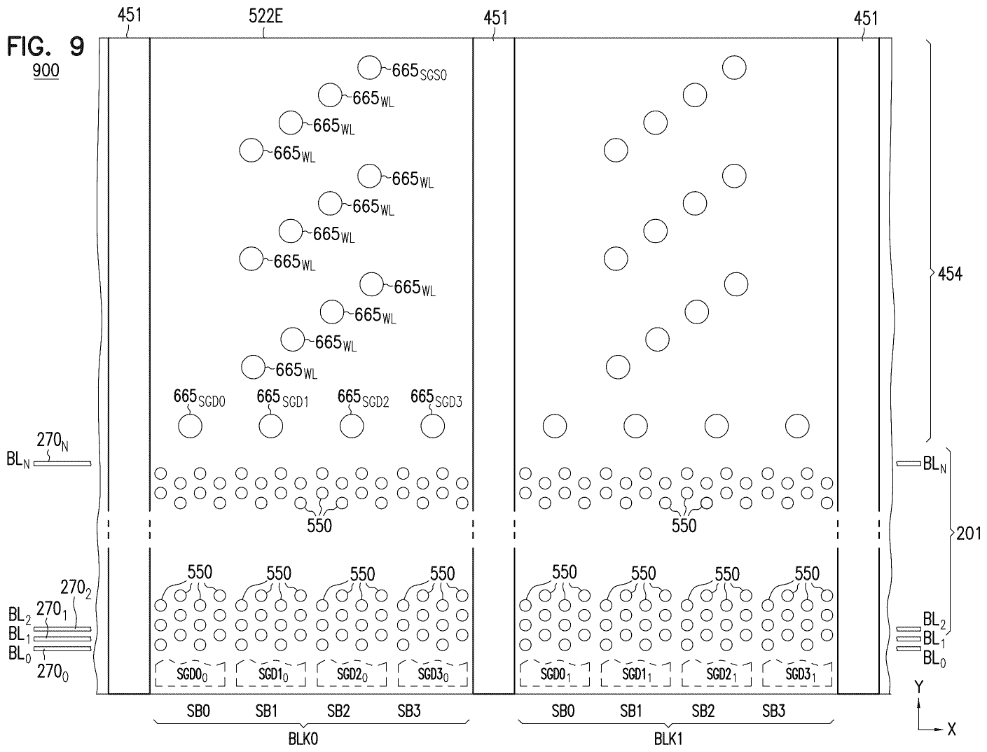

FIG. 9 shows a memory device 900 that can be variation of memory device 200 of FIG. 6A, according to some embodiments described herein. As shown in FIG. 9 and FIG. 6A, memory device 900 can include elements that are similar to or the same as the elements of memory device 200. For simplicity, descriptions of similar or the same elements between memory devices 200 and 900 are not repeated. As shown in FIG. 9, memory device 900 includes conductive contacts (e.g., conductive contacts 665_{WL}) like the conductive contacts of memory device 200 shown in FIG. 6A. Memory device 900 also includes conductive lines (like conductive lines 656 in FIG. 6B) coupled to the conductive contacts. For simplicity, such conductive lines are omitted from FIG. 9.

In comparison with memory device 200 (FIG. 6A), memory device 900 (FIG. 9) can include a higher number of conductive contacts (e.g., conductive contacts 665_{WL}) in region 454. The pattern (e.g., arrangement) of conductive contacts 665_{WL} in region 454 in FIG. 9 can also be different from the pattern of conductive contacts 665_{WL} in FIG. 6A. FIG. 9 shows an example where the conductive contacts (e.g., conductive contacts 665_{WL} and 665_{SGS0}) are formed in four rows, such as four rows side-by-side in the X-direction or three rows arranged diagonally with respect to the Y-X directions. Improvements and benefits of memory device 900 are similar to or the same as improvements and benefits of devices 200 and 200′ described above.

The arrangement of the conductive contacts (e.g., conductive contacts 665_{WL} and 665_{SGS0}) of the memory devices described above (e.g., memory device 200 in FIG. 6A, memory device 800A in FIG. 8A, memory device 800C in FIG. 8C, and memory device 900 in FIG. 9) are examples. However, other arrangements can be used.

The above description with reference to FIG. 2 through FIG. 9 describes the structure of memory devices 200, 200′, 800A, 800B, 800C, 800D, and 900. Some or all of the structure of memory devices 200, 200′, 800A, 800B, 800C, 800D, and 900 can be formed using processes associated with the processes described below with reference to FIG. 10 through FIG. 26BB.

FIG. 10 through FIG. 26BB show different views of elements during processes of forming a memory device 1000, according to some embodiments described herein. FIG. 10 shows a side view (e.g., cross-section) in the Y-direction of a portion of memory device 1000. The side view of memory device 1000 in FIG. 10 is similar to the side view of memory device 200 of FIG. 7A. In FIG. 10, the region included in memory array 201′ is similar to the region included in memory array 201 of memory device 200 in FIG. 6A and FIG. 7A. Region 454′ in FIG. 10 is similar to region 454 of memory device 200 in FIG. 6A and FIG. 7A.

The processes associated with FIG. 10 include forming dielectric materials (levels of dielectric materials) 1021 and dielectric materials (levels of dielectric materials) 1022 over substrate 1099. Dielectric materials 1021 can include silicon dioxide. Dielectric materials 1022 can include silicon nitride. As shown in FIG. 10, memory device 1000 can include levels 1001 through 1013, which are physical levels of the structure of memory device 1000. Dielectric materials (e.g., silicon nitride) 1022 can be formed on respective levels 1001 through 1012. Dielectric materials (e.g., silicon dioxide) 1021 can be formed on levels (not labeled) that are interleaved with respective levels 1001 through 1012.

Substrate 1099 is similar to (e.g., can correspond to) substrate 599 of memory device 200 shown in FIG. 5A and FIG. 7A. Dielectric materials 1021 and 1022 can be sequentially formed one material after another over substrate 1099 in an interleaved fashion, such that dielectric materials 1021 can be interleaved with dielectric materials 1022. As shown in FIG. 10, dielectric materials 1021 and 1022 can include respective edges 1022E. Edges 1022E can be aligned (e.g., vertically aligned) with each other in the Z-direction. As shown in FIG. 10, dielectric materials 1021 and 1022 can form tiers (tiers of materials) 1025. Tiers 1025 are located one over another in the Z-direction. Each tier 1025 can include a respective level of dielectric material 1021 and a respective level of dielectric material 1022. In levels 1001 through 1013, distance from one level to the next immediate level can correspond to the thickness (in the Z-direction) of one tier 1025.

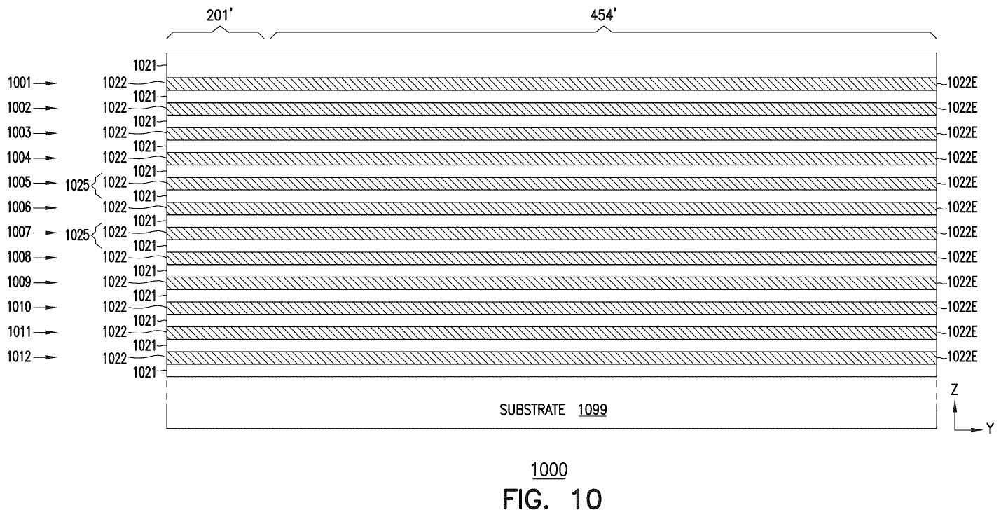

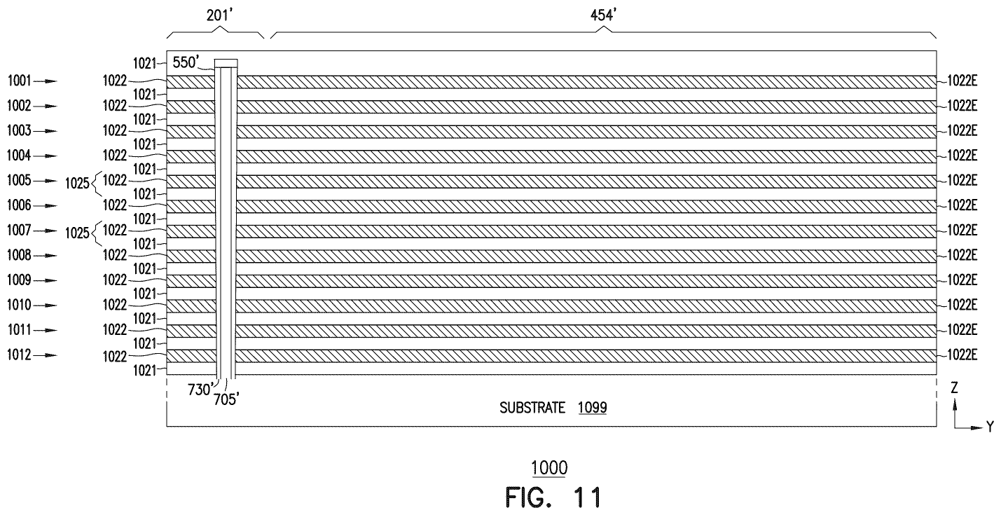

FIG. 11 shows memory device 1000 after a pillar (memory cell pillar) 550′ including structure 730′ and a dielectric material 705′ are formed. Pillar 550′, structure 730′, and dielectric material 705′ are similar to (e.g., can correspond to) pillar 550, structure 730, and dielectric material 705, respectively, of memory device 200 of FIG. 7A. Pillar 550′ is associated with a string of memory cells (not labeled in FIG. 11) like memory cells 210, 211, 212, and 213 of pillar 550 of memory device 200 of FIG. 7A. Although not shown in FIG. 11, the processes associated with FIG. 11 also form other memory cell pillars (like pillars 550 in FIG. 6A) and associated memory cells in the region included in memory array 201′ of memory device 1000.

In FIG. 11, forming pillar 550′ can include removing (exhuming) dielectric materials 1021 and 1022 at the location of pillar 550′ to form an opening (e.g., hole, not labeled) at the location of pillar 550′, and then forming pillars 550′ (which include structure 730′ and dielectric material 705′) in the location of the opening.

FIG. 12 shows memory device 1000 after formation of additional levels of dielectric materials 1021 and 1022, a level (e.g., layer) of material (e.g., carbon nitride) 1222, a level (e.g., layer) of material (e.g., silicon dioxide) 1231, and a structure (e.g., hard mask or photoresist) 1240. As shown in FIG. 12, the additional levels of dielectric materials (e.g., silicon nitride) 1022 can be formed on respective levels 1001A through 1001D. The additional levels of dielectric materials (e.g., silicon dioxide) 1021 can be formed on levels (not labeled) that are interleaved with respective levels 1001A through 1001D.

The processes associated with FIG. 12 can also form a contact structure 560′ over pillar 550′. Contact structure 560′ is similar to contact structure 560 of FIG. 5A and FIG. 5B. Contact structure 560′ in FIG. 12 can be considered as part of pillar 550′. As shown in FIG. 12, contact structure 560′ can extend through the levels of additional dielectric materials 1021 and 1022. Contact structure 560′ can include a conductive material to allow electrical connection between pillar 550′ and a data line (formed in subsequent processes) of memory device 1000. Contact structure 560′ can include a dielectric material (e.g., a vertical dielectric liner on vertical side wall, not shown, of contact structure 560′) to separate (electrically separate) the conductive material of contact structure 560′ from the levels of additional dielectric materials 1021 and 1022.

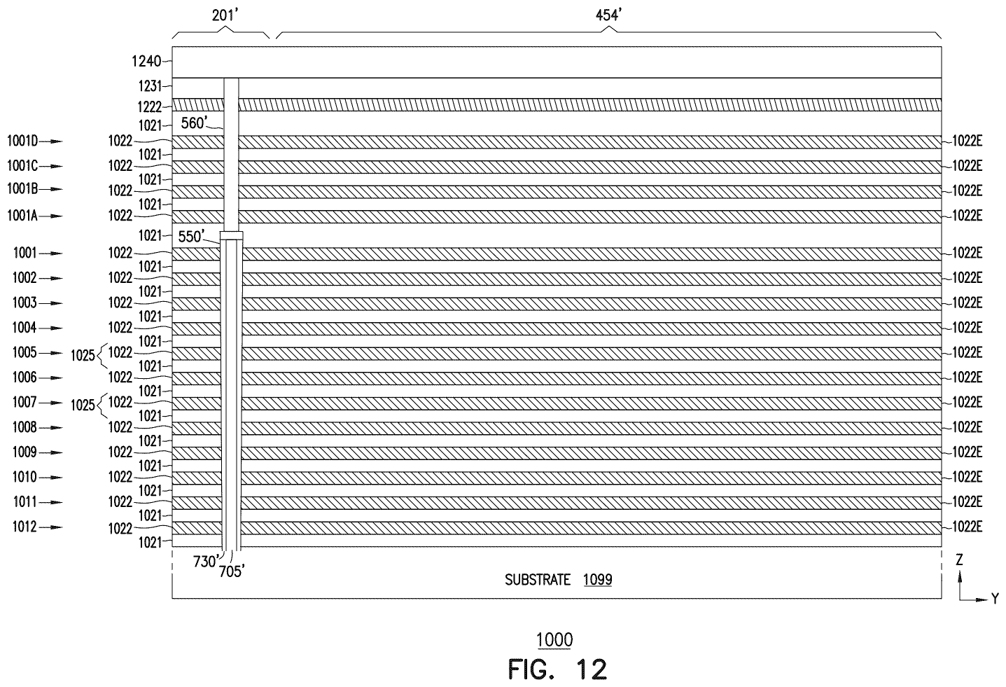

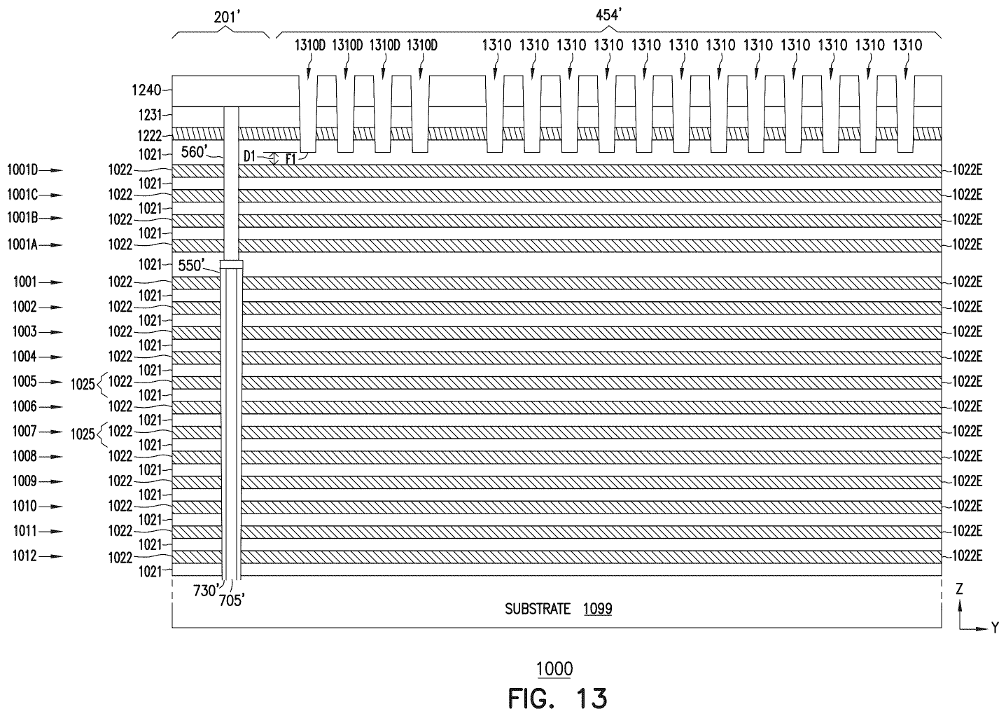

FIG. 13 shows memory device 1000 after openings (e.g., holes) 1310 and 1310D are formed. Forming openings 1310 and 1310D can include removing (e.g., patterning) a portion of structure 1240 at the location of openings 1310 and 1310D, then removing a portion of material 1231, a portion of material 1222, and a portion of dielectric material 1021.

As shown in FIG. 13, openings (e.g., holes) 1310 and 1310D can have bottoms (not labeled) at a depth F1. The bottoms of openings 1310 and 1310D can be at a distance (in the Z-direction) D1 from level 1001D at which a dielectric material (e.g., silicon nitride) 1022 is located. Distance D1 can be less than the thickness (in the Z-direction) of one tier 1025. For example, distance D1 can be similar to (or the same as) the thickness (in the Z-direction) of one level (e.g., one tier oxide) of dielectric material (e.g., silicon dioxide) 1021.

In subsequent processes of forming memory device 1000, conductive contacts (e.g., four conductive contacts similar to conductive contact 665_{SGD0} in FIG. 7A) associated with drain select gates (e.g., similar to four select gates 260_{A}, 260_{B}, 260_{C}, and 260_{D}) of memory device 1000 can be formed at the locations of openings 1310D. In subsequent processes of forming memory device 1000, conductive contacts (e.g., similar to conductive contact 665_{WL} in FIG. 7A) associated with the control gates of memory device 1000 can be formed at the locations of openings 1310D.

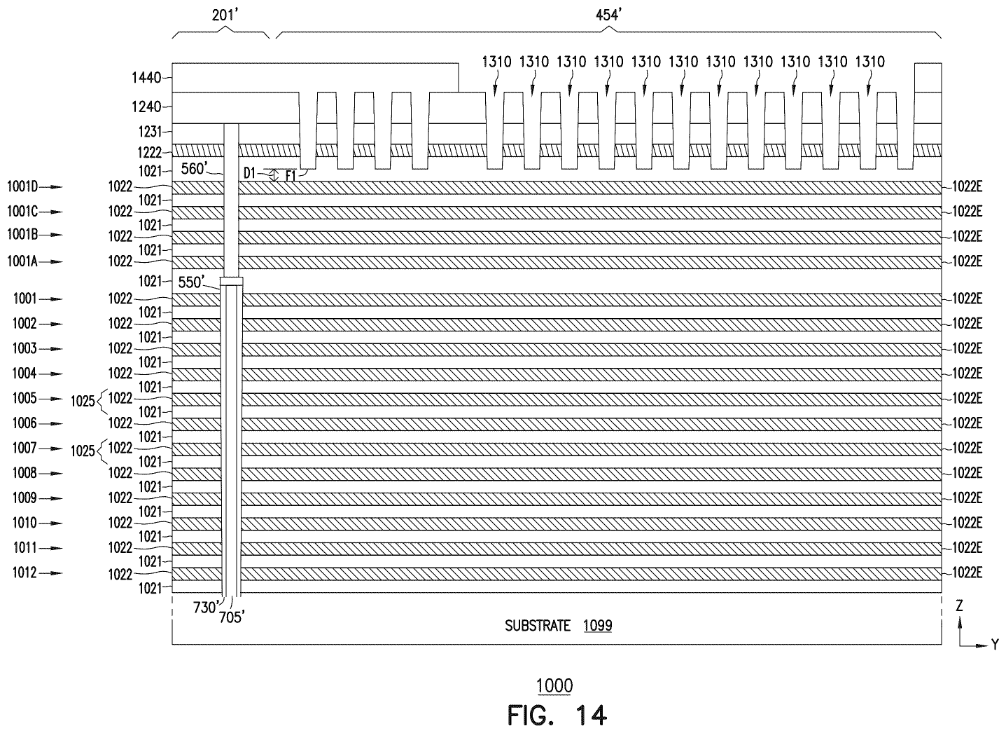

FIG. 14 shows memory device 1000 after a structure 1440 is formed over openings 1310D (labeled in FIG. 13) and openings 1301 and then a portion of structure 1440 over openings 1310 is removed.

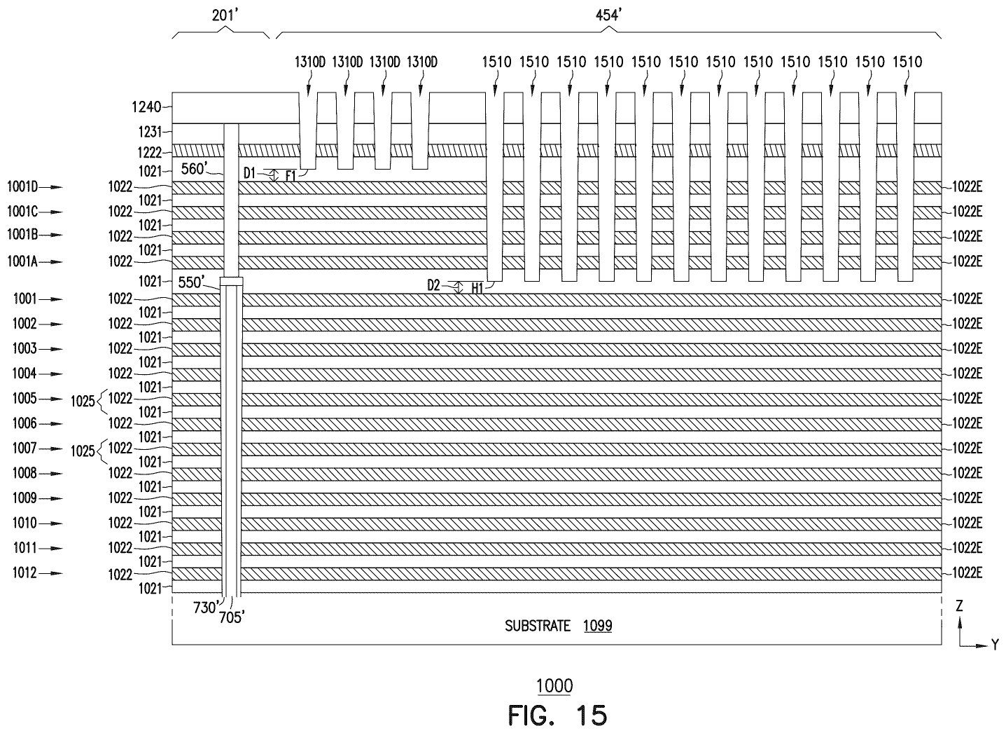

FIG. 15 shows memory device 1000 after openings (e.g., holes) 1510 are formed and structure 1440 is removed. Forming openings 1510 can include removing a portion of dielectric materials 1021 and 1022 at openings 1310 (labeled in FIG. 14). As shown in FIG. 14 and FIG. 15, the processes associated with FIG. 15 can include increasing the depths (in the Z-direction) of openings 1310 (FIG. 14) from the depth F1 to a depth H1 above level 1001 (FIG. 15).

As shown in FIG. 15, openings (e.g., holes) 1510 can have bottoms (not labeled) at depth H1. The bottoms of openings 1510 can at a distance (in the Z-direction) D2 from level at which a dielectric material (e.g., silicon nitride) 1022 is located. Distance D2 can be similar to or the same as distance D1. Distance D2 can be less than the thickness (in the Z-direction) of one tier 1025. For example, distance D2 can be similar to (or the same as) the thickness (in the Z-direction) of one level (e.g., one tier oxide) of dielectric material (e.g., silicon dioxide) 1021.

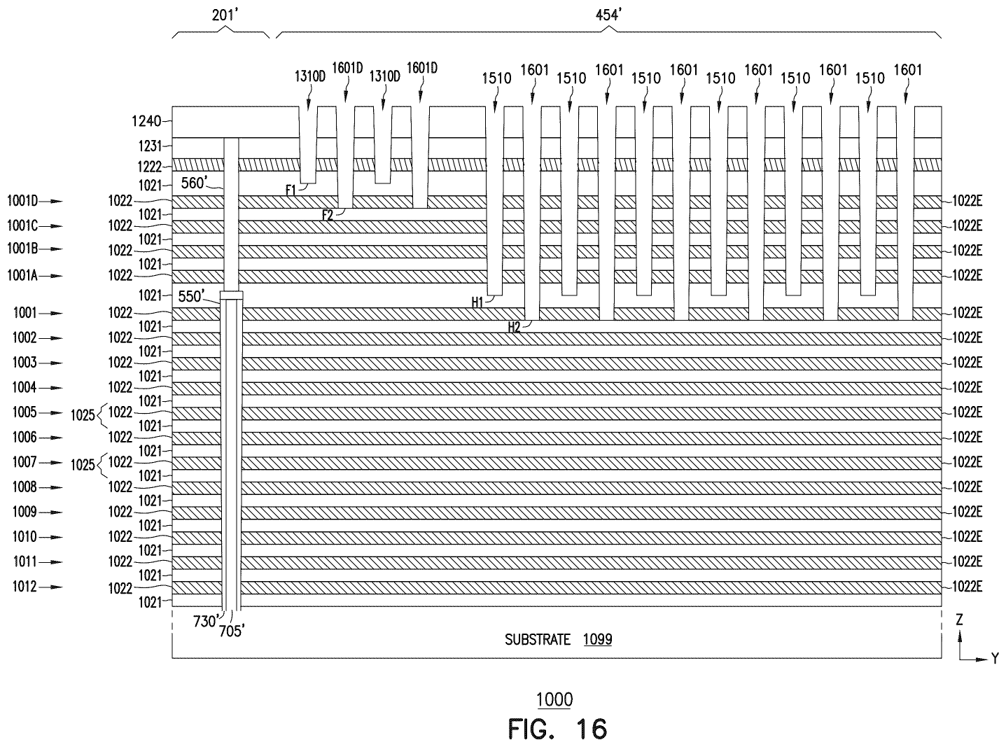

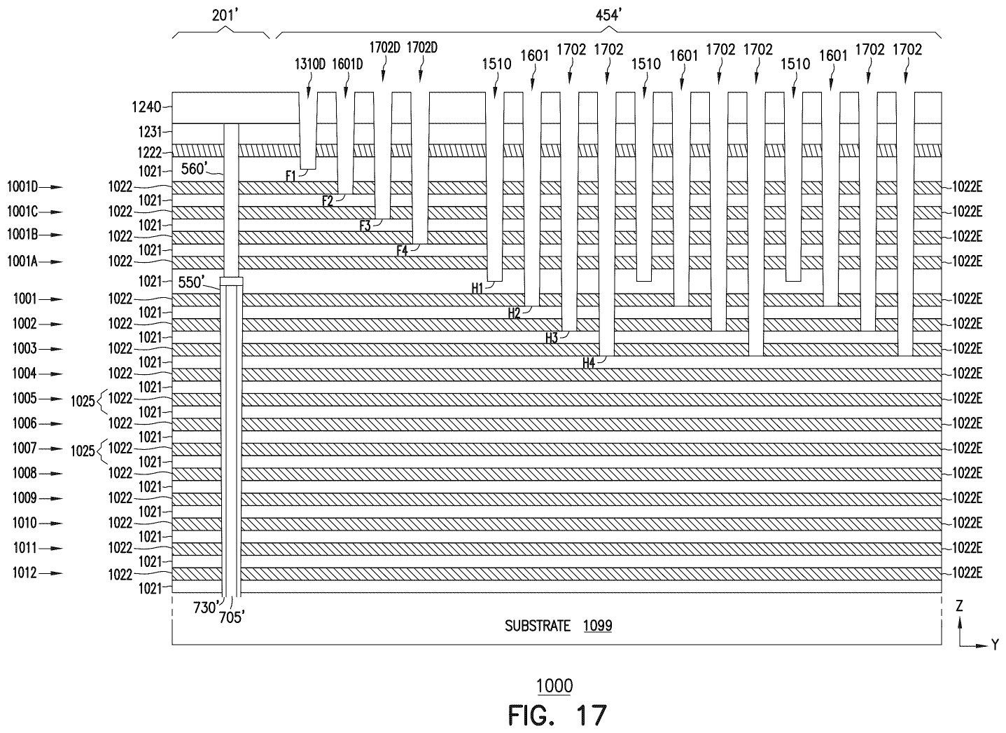

FIG. 16 shows memory device 1000 after openings (e.g., holes) 1601 and 1601D are formed. Forming openings 1601 and 1601D can include removing (selectively removing) a portion of dielectric materials 1021 and 1022 in a group of openings 1510 (fewer than all of openings 1510) of FIG. 15 and a portion of dielectric materials 1021 and 1022 in a group of openings 1310D (fewer than all of openings 1310D) of FIG. 15.

As shown in FIG. 16, the processes associated with FIG. 16 can include increasing the depths (in the Z-direction) of a group of openings 1510 in FIG. 15 from depth H1 shown to a depth H2. As shown in FIG. 16, depth H2 can correspond to the level of a dielectric material (e.g., silicon dioxide) 1021 between levels 1001 and 1002. In FIG. 16, the difference between depth H1 of openings 1510 and depth H2 of openings 1601 can be a thickness (in the Z-direction) of one tier 1025.

As shown in FIG. 16, the processes associated with FIG. 16 can also include increasing the depths (in the Z-direction) of a group of openings 1310D in FIG. 15 from depth F1 to a depth F2. As shown in FIG. 16, depth F2 can correspond to the level of a dielectric material (e.g., silicon dioxide) 1021 between levels 1001C and 1001D. In FIG. 16, the difference between the depth F1 of openings 1310D and depth F2 of openings 1601D can be a thickness (in the Z-direction) of one tier 1025.

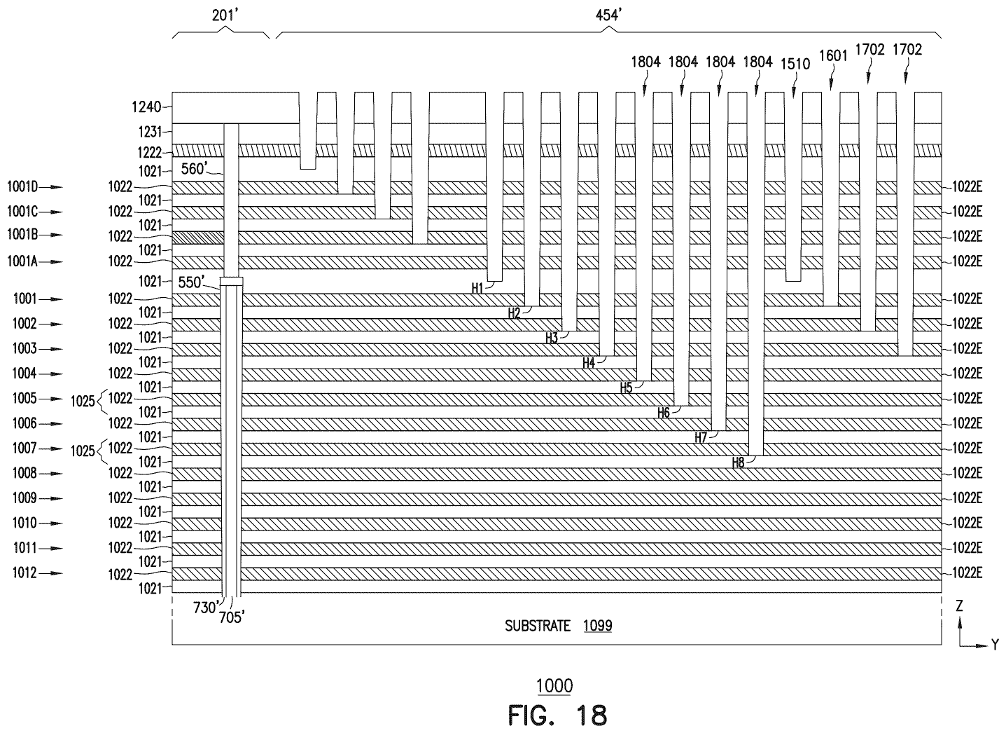

FIG. 17 shows memory device 1000 after openings (e.g., holes) 1702 and 1702D are formed. Forming openings 1702 can include removing (selectively removing) a portion of dielectric materials 1021 and 1022 at a group of openings 1601 of FIG. 16. Forming openings 1702D can include removing (selectively removing) a portion of dielectric materials 1021 and 1022 at a group of openings 1310D and 1601D of FIG. 16.

As shown in FIG. 17, the processes associated with FIG. 17 can include increasing the depths (in the Z-direction) of a group of openings 1510 and 1601 in FIG. 16 from depths H1 and H2 to depths H3 and H4, respectively. Depth H3 can correspond to the level of a dielectric material (e.g., silicon dioxide) 1021 between levels 1002 and 1003. Depth H4 can correspond to the level of a dielectric material (e.g., silicon dioxide) 1021 between levels 1003 and 1004. In FIG. 17, the difference between depth H1 depth H3 can be N=two times the thickness (in the Z-direction) of one tier 1025. Similarly, the difference between depth H2 and depth H4 can be M=two times the thickness (in the Z-direction) of one tier 1025.

As shown in FIG. 17, the processes associated with FIG. 17 can include increasing the depths (in the Z-direction) of a group of openings 1310D and 1601D in FIG. 16 from depths F1 and F2 to depths F3 and F4, respectively. The difference between depth F1 and depth F3 can correspond to two times the thickness (in the Z-direction) of one tier 1025. Similarly, the difference between depth F2 and depth F4 can correspond to two times the thickness (in the Z-direction) of one tier 1025.

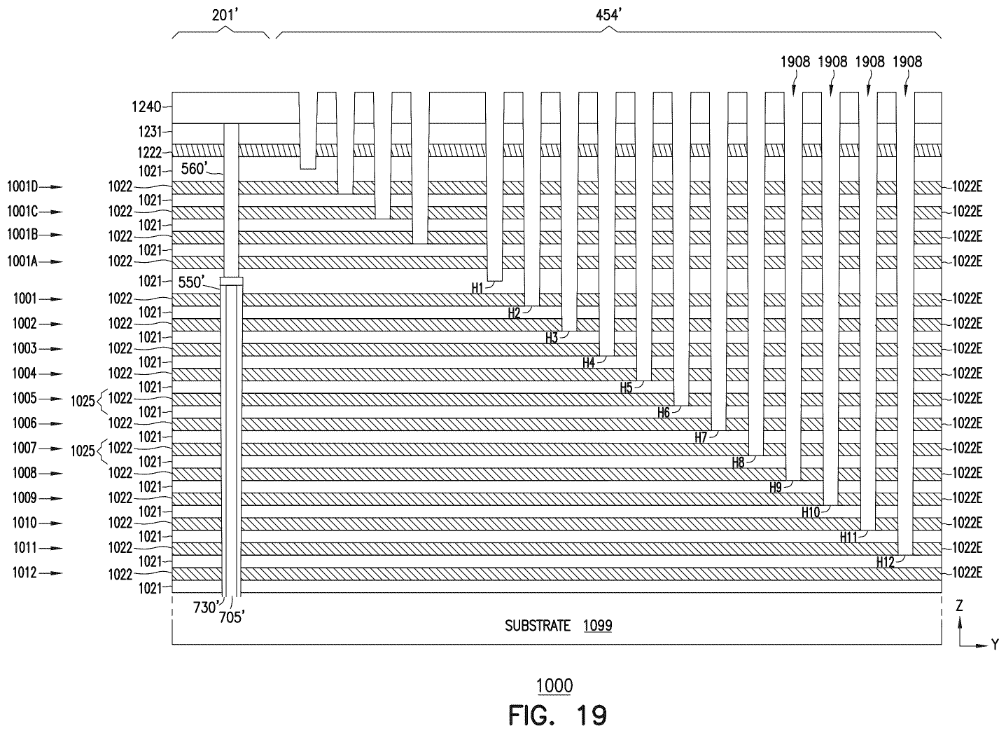

FIG. 18 shows memory device 1000 after openings (e.g., holes) 1804 are formed. Forming openings 1804 can include removing (selectively removing) a portion of dielectric materials 1021 and 1022 at a group of the openings in FIG. 17. As shown in FIG. 18, the processes associated with FIG. 18 can include increasing the depths H1, H2, H3, and H4 to depths H5, H6, H7, and H8, respectively. The difference between depths H1 and H5 can be four times the thickness (in the Z-direction) of tier 1025. Similarly, the difference between depths H2 and H6 can be four times the thickness (in the Z-direction) of tier 1025. The difference between depths H3 and H7 can be four times the thickness (in the Z-direction) of tier 1025. The difference between depths H4 and H8 can be four times the thickness (in the Z-direction) of tier 1025.

FIG. 19 shows memory device 1000 after openings (e.g., holes) 1908 are formed. Forming openings 1908 can include removing (selectively removing) a portion of dielectric materials 1021 and 1022 at a group of openings 1510, 1601, and 1702 in FIG. 18. As shown in FIG. 19, the processes associated with FIG. 19 can include increasing the depths (in the Z-direction) of a group of openings in FIG. 18 from depths H1, H2, H3, and H4 (of respective openings 1510, 1601, and 1702 in FIG. 18) to depths H9, H10, H11, and H12, respectively. The difference between depths H1 and H9 can be eight times the thickness (in the Z-direction) of tier 1025. Similarly, the difference between depths H2 and H10 can be eight times the thickness (in the Z-direction) of tier 1025. The difference between depths H3 and H11 can be eight times the thickness (in the Z-direction) of tier 1025. The difference between depths H4 and H12 can be eight times the thickness (in the Z-direction) of tier 1025.

Thus, forming the openings in the processes associated with FIG. 15 through FIG. 19, as described above, can include increasing the depth of a particular opening from one depth to another depth. The difference in the depths can be based on the thickness of tier 1025. For example, as described above with reference to FIG. 15 through FIG. 19, difference in the depths can be the thickness of N or M times the thickness of tier 1025, where N or M can be a multiple of two.

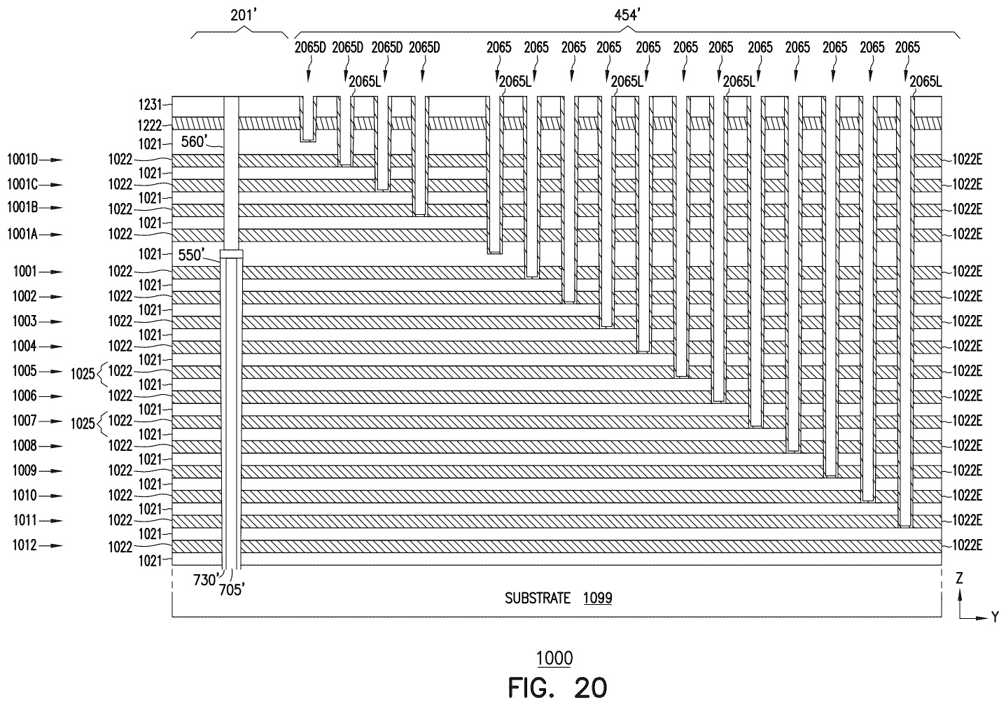

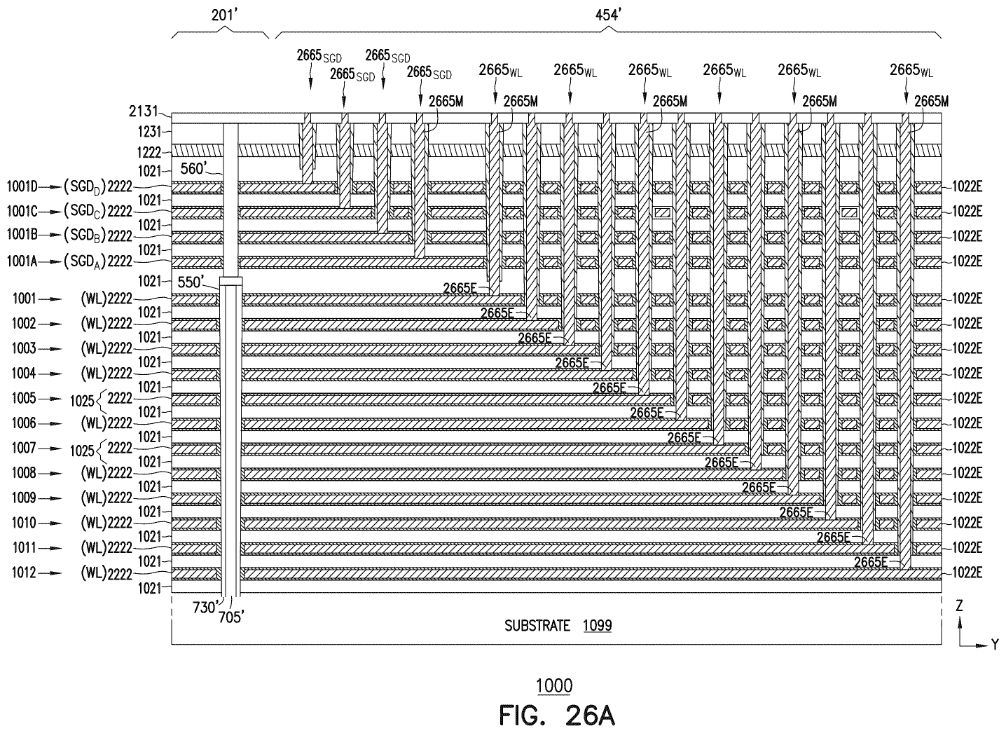

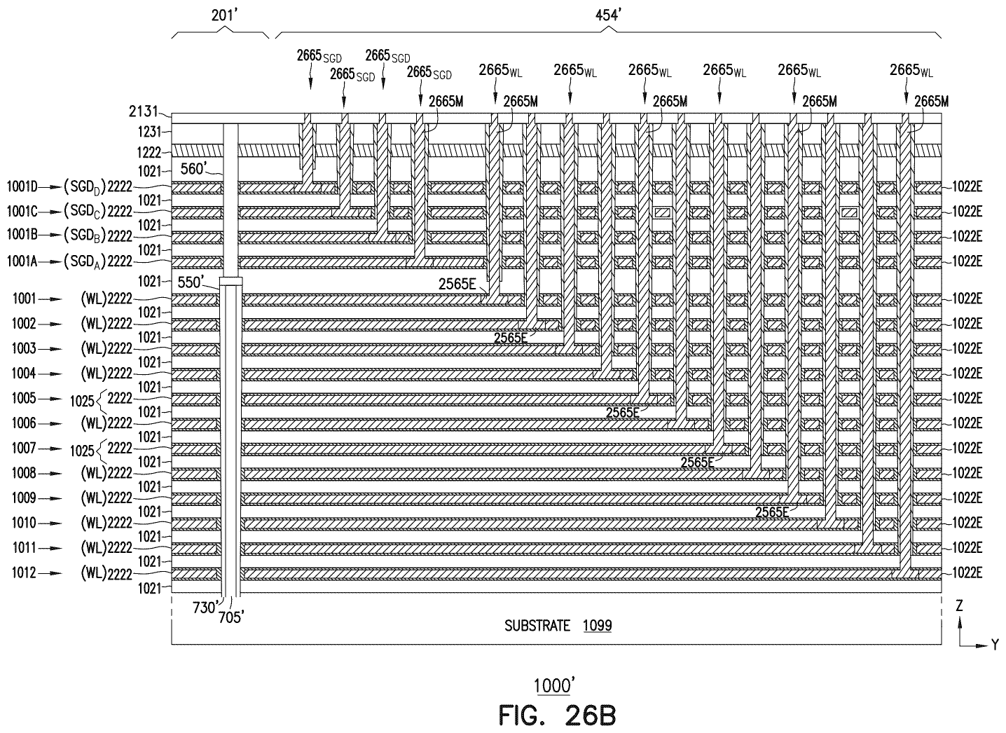

FIG. 20 shows memory device 1000 after structure 1240 (shown in FIG. 19) is removed, and dielectric materials 2065L are formed in respective openings 2065 and 2065D. In FIG. 20, openings (e.g., holes) 2065 and 2065D are the same as the openings formed in the processes associated with FIG. 13 and FIG. 19. An example of dielectric materials 2065L includes silicon dioxide. As shown in FIG. 20, dielectric material 665L in a respective openings 2065 and 2065D can be a relatively thin layer (thin layer of dielectric material). Thus, dielectric material 2065L can be called a dielectric liner (e.g., dielectric liner on a vertical side wall of a respective conductive contact, such as conductive contact 2665_{WL}, which will be formed in the processes associated with FIG. 26A or FIG. 26B.)

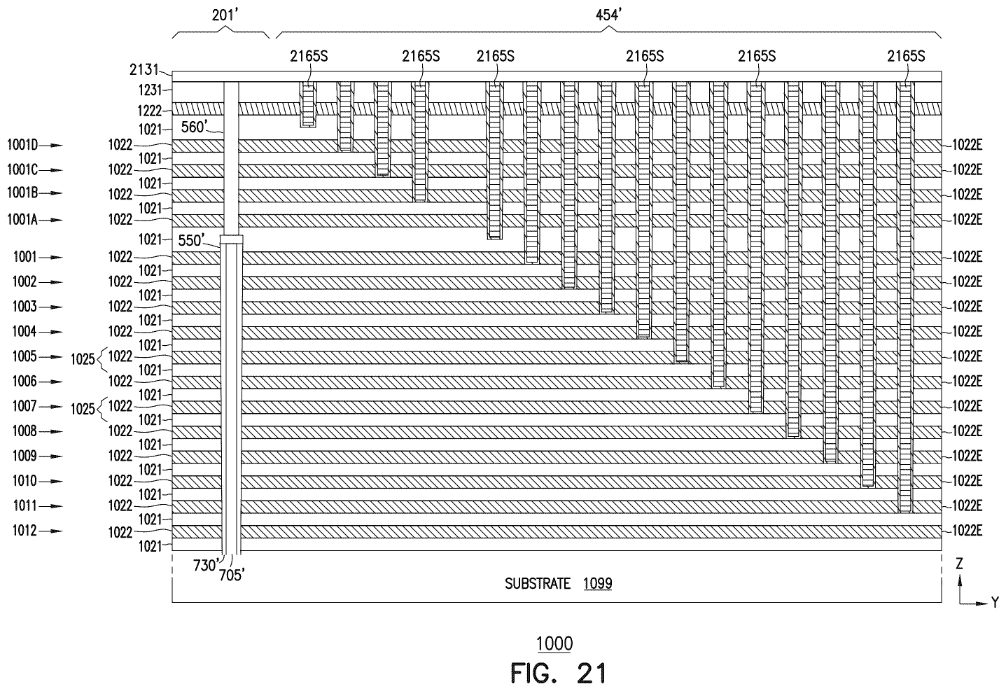

FIG. 21 shows memory device 1000 after a material 2165S is formed (e.g., filled) in openings 2065 and 2065D. For simplicity, material 2165S in only some of openings 2065 and 2065D is labeled. Material 2165S can be a sacrificial material that will be removed in subsequent processes. An example of material 2165S includes carbon. The processes associated with FIG. 21 can include a chemical mechanical polishing (CMP) process after material 2165S is formed. The processes associated with FIG. 21 include forming a material (e.g., silicon dioxide) 2131 over other materials as shown in FIG. 21.

FIG. 22A shows memory device 1000 after dielectric materials 1022 (e.g., silicon nitride) in FIG. 21 are removed (e.g., exhumed) from locations 2202 in FIG. 22A. Locations 2202 are voids (empty spaces) that were occupied by dielectric materials 1022 in FIG. 21. In subsequent processes, dielectric liners and conductive materials can be formed in locations 2022 to form part of respective control gates of memory device 1000.

FIG. 22B shows memory device 1000 after dielectric liners 2223L1, 2223L2, and 2223V are formed. Forming dielectric liners 2223L1, 2223L2, and 2223V can include forming a dielectric material adjacent (e.g., on) the materials (e.g., dielectric materials 1022) that are exposed at location 2202. Dielectric liners 2223L1, 2223L2, and 2223V can be formed concurrently (e.g., formed simultaneously in the same process step). Dielectric liners 2223L1, 2223L2, and 2223V can correspond to dielectric liners 523L1, 523L2, and 523V, respectively of memory device 200 of FIG. 7A. Thus, dielectric liners 2223L1, 2223L2, and 2223V can include a dielectric material (e.g., high-k dielectric material) similar to or the same as dielectric liners 523L1, 523L2, and 523V of FIG. 7A.

FIG. 22C shows memory device 1000 after conductive materials (levels of conductive materials) 2222 are formed in locations 2202 (labeled in FIG. 22B). In FIG. 22C, forming conductive materials 2222 can include forming (e.g., filling) a conductive material (or a combination of conductive materials) 2222 in locations 2022 (labeled in FIG. 22B). In FIG. 22C, conductive materials 2222 can be concurrently formed (e.g., formed simultaneously in the same process step) in locations 2022 (labeled in FIG. 22B). Conductive materials 2222 can correspond to conductive materials 522 of memory device 200 of FIG. 7A. Thus, conductive materials 2222 can be similar to (or the same as) conductive materials 522 of memory device 200 of FIG. 7A.

As shown in FIG. 22C, some of conductive materials 2222 (some of the levels of conductive materials 2222) can form part of respective control gates associated with signals WL of memory device 1000. The control gates associated with signals WL can be similar to the control gates associated with signal WL0₀, WL1₀, WL2₀, and WL3₀ of memory device 200 of FIG. 7A.

In FIG. 22C, some of conductive materials 2222 (some of the levels of conductive materials 2222) can form part of select lines (e.g., four select lines) associated with signals SGD_{A}, SGD_{B}, SGD_{C}, and SGD_{D} of memory device 1000. The select lines associated with signals SGD_{A}, SGD_{B}, SGD_{C}, and SGD_{D} can be similar to select lines 280_{A}, 280_{B}, 280_{C}, and 280p associated with respective signals SGD_{A}, SGD_{B}, SGD_{C}, and SGD_{D} of memory device 200 in FIG. 3B and FIG. 5B.

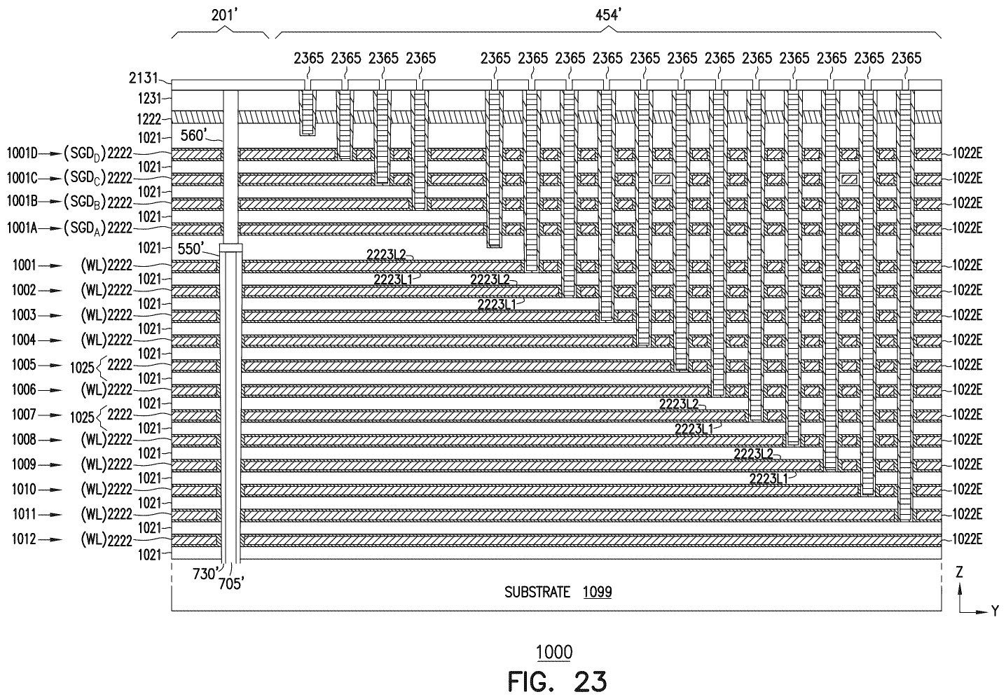

FIG. 23 shows memory device 1000 after openings (e.g., holes) 2365 are formed in material 2131. As shown in FIG. 23, forming openings 2365 can expose material 2165S (formed in FIG. 20) at openings 2365.

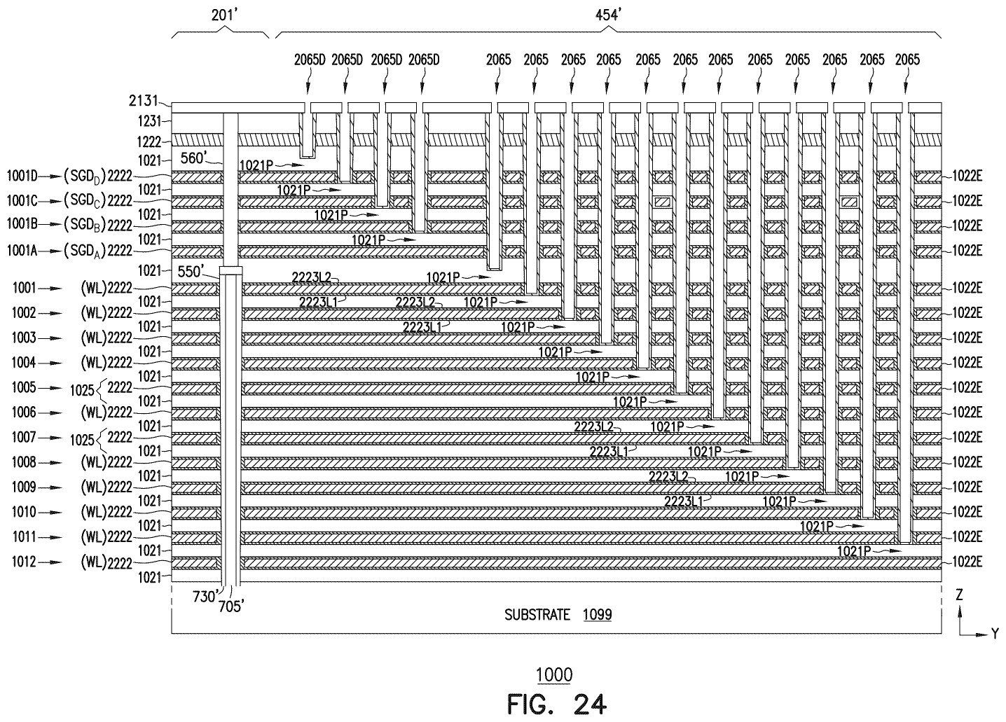

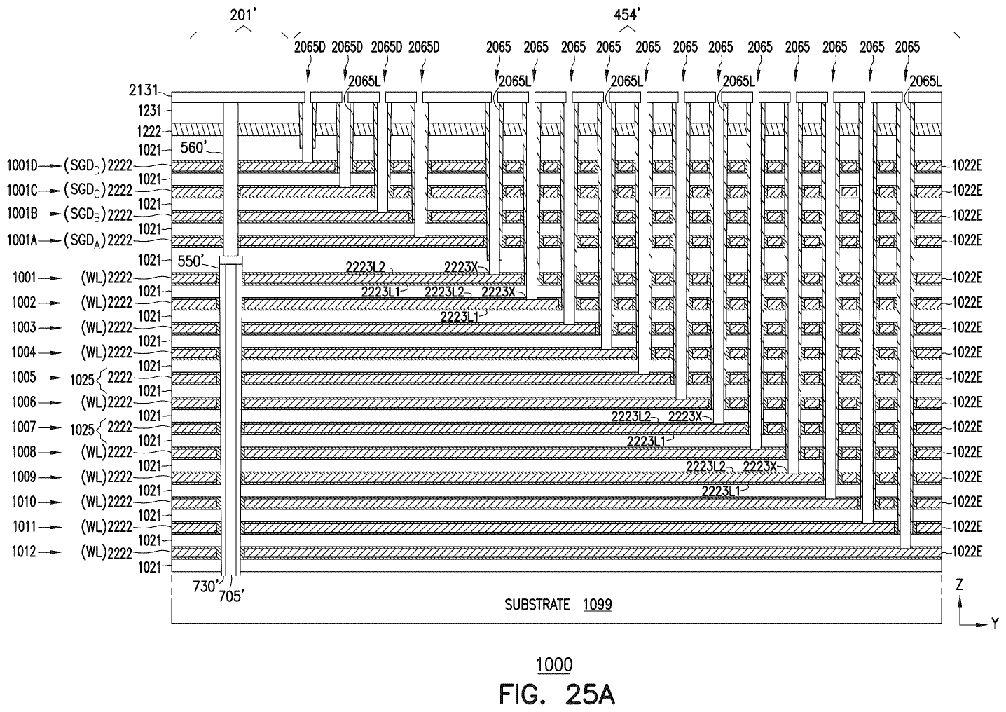

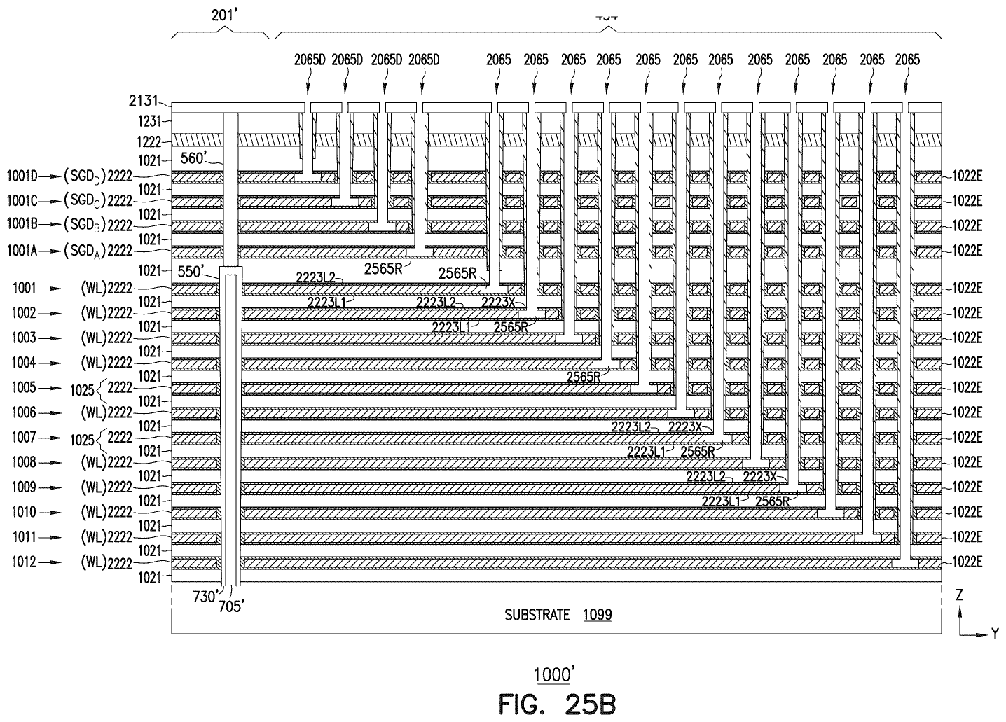

FIG. 24 shows memory device 1000 after material 2165S is removed (e.g., exhumed) from openings 2065 and 2065D. FIG. 24 shows dielectric portions 1021P of respective dielectric materials 1021. As shown in FIG. 24, dielectric portions 1021P can be directly located below respective openings 2065 and 2065D. In subsequent processes (FIG. 25A), respective portions (e.g., bottom portions) of dielectric material 2065L in openings 2065 and 2065D at the locations above dielectric portions 1021P can be removed (e.g., punched). Then, dielectric portions 1021P can also be removed (FIG. 25A). Further, in subsequent processes (FIG. 25A), respective portions of dielectric liners 2223L2 at the locations under dielectric portions 1021P can also be removed to form openings 2223X (FIG. 25A).

FIG. 25A shows memory device 1000 after respective portions (e.g., bottom portions) of dielectric material 2065L in openings 2065 and 2065D at the locations of dielectric portions 1021P (labeled in FIG. 24) are removed (e.g., punched). FIG. 25A also shows memory device 1000 after dielectric portions 1021P (labeled in FIG. 24) are removed. FIG. 25A also shows memory device 1000 after respective portions of dielectric liners 2223L2 are removed to form respective openings 2223X (at the locations at which respective portions of dielectric liners 2223L2 were removed). As shown in FIG. 25A, the depths of openings (e.g., holes) 2065 and 2065D from FIG. 24 to FIG. 25A are increased (e.g., increased at least by the thickness of one tier oxide of tier 1025) as a result of the processes associated with FIG. 25A.

As shown in FIG. 25A, openings (e.g., holes) 2065 and 2065D can extend through respective control gates (associated with signals WL), the levels of dielectric materials 1021, and openings 2223X, such that respective portions of conductive materials 2222 are exposed at respective openings 2065 and 2065D.

The processes of forming memory device 1000 can continue from the processes associated with FIG. 25A to the processes associated with FIG. 26A. However, the processes of forming memory device 1000 can alternatively include processes associated with FIG. 25B, as described below.

FIG. 25B shows memory device 1000 after recesses 2565R are formed in respective conductive materials 2222 in alternative processes of forming memory device 1000. In FIG. 25B, recesses 2565R are voids (empty spaces) in conductive materials 2222. Forming recesses 2565R can include removing (e.g., etching) respective portions of conductive materials 2222 at the locations of recesses 2565R. In subsequent alternative processes (FIG. 26B) of forming memory device 1000, conductive contacts will be formed in openings 2065 and 2065D, such that portions (e.g., end portions) of the conductive contacts are located in respective recesses 2565R.

The processes of forming memory device 1000 can continue from the processes associated with FIG. 25B to the processes associated with FIG. 26B (skipping the processes associated with FIG. 26A) if the? associated with FIG. 25B are performed. However, the processes of forming recesses 2565R associated with FIG. 25B can be skipped (not performed). Thus, if the processes of forming recesses 2565R associated with FIG. 25B are skipped, the processes of forming memory device 1000 can continue from the processes associated with FIG. 25A to the processes associated with FIG. 26A (skipping the processes associated with FIG. 25B and FIG. 26B).

FIG. 26A shows memory device 1000 after conductive contacts 2665_{WL} and 2665_{SGD} including are formed. For simplicity, only some of conductive contacts 2665_{WL} are labeled in FIG. 26A. Forming conductive contacts 2665_{WL} and 2665_{SGD} can including forming (e.g., filling) conductive materials 2665M in openings 2065 and 2065D. Conductive materials 2665M can be the same as (or alternatively different from) conductive materials 2222 that form the control gates of memory device 1000. Conductive contacts 2665_{WL} and 2665_{SGD} can be similar to conductive contacts 665_{WL} and 665_{SGDO}, respectively, of memory device 200 FIG. 7A. As shown in FIG. 26A, conductive contacts 2665_{WL} and 2665_{SGD} can have respective portions (e.g., end portions) 2665E going through respective openings 2223X (labeled in FIG. 25A) and contacting respective conductive materials 2222. Portions 2665E can be similar to portion 665E of memory device 200 of FIG. 7A.

As described above, the processes of forming memory device 1000 can continue from the processes associated with FIG. 25B to the processes associated with FIG. 26B (skipping the processes associated with FIG. 26A) if the? associated with FIG. 25B are performed.

FIG. 26B shows memory device 1000 after conductive contacts 2665_{WL} and 2665_{SGD} including are formed alternative processes of forming memory device 100. For simplicity, only some of conductive contacts 2665_{WL} are labeled in FIG. 26B. Forming conductive contacts 2665_{WL} and 2665_{SGD} can including forming (e.g., filling) conductive materials 2665M in openings 2065 and 2065D. Conductive materials 2665M can be the same as (or alternatively different from) conductive materials 2222 that form the control gates of memory device 1000. Conductive contacts 2665_{WL} and 2665_{SGD} can be similar to conductive contacts 665_{WL} and 665_{SGDO}, respectively, of memory device 200′ FIG. 7F. As shown in FIG. 26B, conductive contacts 2665_{WL} and 2665_{SGD} can have respective portions (e.g., end portions) 2665E′ going through respective openings 2223X (labeled in FIG. 25B) and contacting respective conductive materials 2222. Portions 2665E′ can be similar to portion 665E of memory device 200′ of FIG. 7F.

The processes associated with FIG. 10 through FIG. 26B show example connections between the conductive contacts (conductive contacts 2665_{WL}) and respective control gates of memory device 1000. However, memory device 1000 can be formed to have alternative patterns of the connections between the conductive contacts and the control gates, such as the patterns shown in FIG. 8A, FIG. 8B, FIG. 8C, and FIG. 8D, or other patterns.

As described above, in a particular process that increases the current depth of a particular opening to a new depth, the current depth can be increased by an amount based on the equation R=2ⁱ*T_1025, where R is an integer representing the number of tiers (single tier or multiple tiers), symbol “*” represents multiplication, and “T_1025” represent the thickness of tier 1025, and “i” includes zero and positive integers that can be increased by one (e.g., i=0, 1, 2, 3, etc.) from one process to the next process. For example, in FIG. 16, depth H1 of opening 1510 can be increased by R=2⁰*T_1025=1*T_1025=one thickness of tier 1025 (e.g., from depth H1 to depth H2). In another example, in FIG. 17, depth H1 of opening 1510 can be increased by R=2¹*T_1025=2*T_1025=two times the thickness of tier 1025 (e.g., from depth H1 to depth H3 or from depth H2 to depth H4). In another example, in FIG. 18, depth H1 of opening 1601 can be increased by R=2²*T_1025=2*T_1025=four times the thickness of tier 1025 (e.g., from depth H1 to depth H5, from depth H2 to depth H6, from depth H3 to depth H7, or from depth H4 to depth H8). In another example, in FIG. 19, the depth of an opening 1702 (labeled in FIG. 17) can be increased by R=2³*T_1025=8*T_1025=eight times the thickness of tier 1025 (e.g., from depth H1 to depth H9, from depth H2 to depth H10, from depth H3 to depth H11, or from depth H4 to depth H12).

Thus, the rate of an increase in depths of respective openings from one process to the next process can be based on equation R=2ⁱ*T_1025, where variable “i” can be increased by one from one process to the next immediate process. The processes of forming memory device 1000 show processes of forming a certain number (e.g., 12) of conductive contacts as an example. However, similar processes can be used to form numerous conductive contacts associated with numerous control gate.

The processes of forming memory device 1000 described above with reference to FIG. 10 through FIG. 26B can include other processes to form a complete memory device (e.g., memory device 1000). Such processes are omitted from the above description so as not to obscure the subject matter described herein.

Improvements and benefits of memory device 1000 are similar to or the same as improvements and benefits devices 200 and 200′ described above. Further, forming memory device 1000 as described above can provide additional improvements and benefits some alternative techniques. For example, in an alternative technique, the processes of forming memory device 1000 may include forming additional structures (e.g., implanted structures) at the locations of portions 522P (FIG. 7E) before conductive materials 522 are formed and then removing such additional structures when conductive contacts 2665_{WL} are formed. However, as described above with reference to FIG. 10A through FIG. 26B, such additional structures are not formed in the processes of forming memory device 1000. Thus, forming memory device 1000 can have fewer processing steps in comparison with that of the alternative techniques. This can lead to relatively lower cost for forming memory device 1000 in comparison with that of the alternative techniques. Moreover, forming memory device 1000 as described above with reference to FIG. 10A through FIG. 26B can have an improved (e.g., lower) thermal budget in comparison with that of the alternative techniques. For example, a relatively higher thermal budget may be used in the alternative techniques to form the mentioned additional structures. However, in memory device 1000, the thermal budget may be lower because such additional structures are not formed.

The illustrations of apparatuses (e.g., memory devices 100, 200, 200′, 800A, 800B, 899C, 800D, 900, and 1000) and methods (e.g., method of forming memory device 1000) are intended to provide a general understanding of the structure of various embodiments and are not intended to provide a complete description of all the elements and features of apparatuses that might make use of the structures described herein. An apparatus herein refers to, for example, either a device (e.g., any of memory devices 100, 200, 200′, 800A, 800B, 899C, 800D, 900, and 1000) or a system (e.g., a computer, a cellular phone, or other electronic systems) that includes a device such as any of memory devices 100, 200, 200′, 800A, 800B, 899C, 800D, 900, and 1000.

Any of the components described above with reference to FIG. 1 through FIG. 26B can be implemented in a number of ways, including simulation via software. Thus, apparatuses, e.g., memory devices 100, 200, 200′, 800A, 800B, 899C, 800D, 900, and 1000 or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

Memory devices 100, 200, 200′, 800A, 800B, 899C, 800D, 900, and 1000 may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 26B include apparatuses and methods of forming the apparatuses. One of the apparatuses includes: Some embodiments include apparatuses and methods of forming the apparatuses. One of the apparatuses includes: first memory cells and an associated first control gate located on a first level of the apparatus; second memory cells and an associated second control gate located on a second level of the apparatus; a level of dielectric material between the first and second control gates; the second control gate including a conductive material, and a first dielectric liner and a second dielectric liner adjacent respective sides of the conductive material; the second dielectric liner including an opening adjacent a portion of the conductive material; the first dielectric liner extending continuously at the portion of the conductive material; and a conductive contact extending through the first control gate, the level of dielectric material, and the opening of the second dielectric liner and contacting the conductive material of the second control gate. Other embodiments including additional apparatuses and methods are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third,” etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
first memory cells located on a first level of the apparatus;
a first control gate associated with the first memory cells and located on the first level;
a level of dielectric material located on a second level of the apparatus;
second memory cells located on a third level of the apparatus;
a second control gate associated with the second memory cells and located on the third level, the second control gate separated from the first control gate by the level of dielectric material, the second control gate including a conductive material, a first dielectric liner adjacent a first side of the conductive material, and a second dielectric liner adjacent a second side of the conductive material, the second dielectric liner including an opening adjacent a portion of the conductive material, and the first dielectric liner extending continuously at the portion of the conductive material;
a conductive contact extending through the first control gate, the level of dielectric material, and the opening of the second dielectric liner and contacting the conductive material of the second control gate.

2. The apparatus of claim 1, wherein the conductive material of the second control gate extends continuously at a location adjacent the opening of the second dielectric liner.

3. The apparatus of claim 1, wherein the first dielectric liner and the second dielectric liner include a first dielectric material, and the dielectric material located on the second level includes a second dielectric material.

4. The apparatus of claim 1, wherein each of the first dielectric liner and the second dielectric liner includes a dielectric material having a dielectric constant greater than a dielectric constant of silicon dioxide.

5. The apparatus of claim 1, wherein the conductive contact includes a conductive portion between the first dielectric liner and the first dielectric liner, and wherein the conductive portion has a footprint greater than a footprint of the opening of the second dielectric liner.

6. The apparatus of claim 1, wherein the conductive contact extends at least partially into the conductive material of the second control gate.

7. The apparatus of claim 1, wherein the conductive contact includes a conductive portion between the first dielectric liner and the second dielectric liner, wherein the conductive portion contacts the first dielectric liner.

8. The apparatus of claim 1, wherein the conductive contact includes a conductive pillar, and a dielectric material between the conductive pillar and the first control gate.

9. The apparatus of claim 8, wherein the first control gate includes an additional dielectric material adjacent the dielectric material of the conductive contact.

10. The apparatus of claim 1, further comprising:
third first memory cells located on a fourth level of the apparatus;
a third control gate associated with the third memory cells and located on the fourth level, the second control gate including a conductive material; and
an additional conductive contact extending through the second control gate and contacting the conductive material of the third control gate.

11. An apparatus comprising:
first memory cells located on a first level of the apparatus;
a first control gate associated with the first memory cells and located on the first level;
a level of dielectric material located on a second level of the apparatus;
second memory cells located on a third level of the apparatus;
a second control gate associated with the second memory cells and located on the third level, the second control gate separated from the first control gate by the level of dielectric material, the second control gate including a conductive material, a first dielectric liner adjacent a first side of the conductive material; and a second dielectric liner adjacent a second side of the conductive material, the second dielectric liner including an opening, wherein the conductive material extends continuously at a location adjacent the opening of the second dielectric liner; and
a conductive contact extending through the first control gate, the level of dielectric material, and the opening of the second dielectric liner and contacting the conductive material of the second control gate.

12. The apparatus of claim 11, wherein the level of dielectric material includes silicon dioxide, and each of the first dielectric liner and the second dielectric liner includes a dielectric material having a dielectric constant greater than a dielectric constant of the silicon dioxide.

13. The apparatus of claim 11, further comprising an additional conductive contact, wherein:
the first control gate includes an additional conductive material, a first dielectric liner adjacent a first side of the additional conductive material, and a second dielectric liner adjacent a second side of the additional conductive material, the second dielectric liner of first control gate includes including an opening; and
the additional conductive contact extends through the opening of the second dielectric liner of the first control gate and contacting the additional conductive material of the first control gate.

14. The apparatus of claim 13, further comprising a memory cell pillar associated with one of the first memory cell and one of the second memory cells, the memory cell pillar extending through the first control gate and the second control gate, wherein:
the first control gate including a first edge;
the second control gate including a second edge;
the conductive contact is between the memory cell pillar and the first edge, and the first conductive contact is between the memory cell pillar and the second edge; and
the additional conductive contact is between the memory cell pillar and the first edge, and the additional conductive contact between the memory cell pillar and the second edge.

15. The apparatus of claim 14, wherein:
the conductive contact is a first conductive contact, and the additional conductive contact is a second conductive contact; and
the first conductive contact is closer to the memory cell pillar than the second conductive contact, and the first conductive contact includes a length greater than a length of the second conductive contact.

16. The apparatus of claim 15, further comprising third memory cells located on a fourth level of the apparatus, a third control gate associated with the third memory cells and located on the fourth level, and a third conductive contact, wherein:
the second level is between the first level and the fourth level;
the third control gate includes a third conductive material, a first dielectric liner adjacent a first side of the third level of conductive material, and a second dielectric liner adjacent a second side of the third conductive material, the second dielectric liner of the third control gate including an opening;
the third conductive contact extends through the opening of the second dielectric liner of the third control gate and contacting the third conductive material of the third control gate; and
the third conductive contact is closer to the pillar than the first conductive contact, and the length of the first conductive contact is greater than a length of the third conductive contact.

17. A method comprising:
forming levels of first materials interleaved with levels of second materials;
forming memory cells including forming a pillar associated with the memory cells through the levels of first materials and the levels of second materials;
removing a first portion of the levels of first materials and the levels of second materials to form openings in the levels of first materials and the levels of second materials, the openings including a first group of openings and a second group of openings, the first group of openings and the second group of openings having a first depth;
removing a second portion of the levels of first materials and the levels of second materials to increase the first depth of the first group of openings to a second depth;
removing a third portion of the levels of first materials and the levels of second materials to increase the first depth of the second group of openings to a third depth and increase the second depth of a portion of the first group of openings to a fourth depth;
removing portions of the levels of second materials adjacent the first group of openings to increase the third depth;
removing portions of the levels of second materials adjacent the second group of openings to increase the fourth depth; and
forming conductive contacts in the first group of openings and the second group of openings.

18. The method of claim 17, further comprising:
removing the levels of first materials before forming conductive contacts to form spaces at locations occupied by the levels of first materials before the levels of first materials are removed;
forming dielectric liners and forming levels of conductive materials in the spaces, wherein forming the conductive contacts is performed after forming the dielectric liners and after forming the levels of conductive materials; and
wherein the conductive contacts contact respective levels of the levels of conductive materials.

19. The method of claim 18, wherein:
forming the dielectric liners includes removing portions of selected dielectric liners among the dielectric liners before forming the conductive contacts to form openings in the selected dielectric liners and expose the levels of conductive materials at the openings; and
wherein forming the conductive contacts includes forming conductive materials of the conductive contacts such that the conductive materials the conductive contacts extend through respective openings and contact the levels of conductive materials.

20. The method of claim 19, further comprising:
removing portions of the levels of conductive materials exposed at the openings before forming the conductive contacts.
